(19) United States
(12) Patent Application Publication
(10) Pub. No.: US 2023/0200248 A1
(43) Pub. Date: Jun. 22, 2023

(54) ELECTRICAL ENERGY CONVERSION SYSTEM WITH PIEZOELECTRIC ASSEMBLY(S) AND ELECTRICAL TRANSFORMER

(71) Applicant: Commissariat à I'énergie atomique et aux énergies alternatives, Paris (FR)

(72) Inventors: Ghislain DESPESSE, Grenoble Cedex (FR); Mustapha TOUHAMI, Grenoble Cedex (FR); Valentin BRETON, Grenoble Cedex (FR)

(73) Assignee: Commissariat à l'énergie atomique et aux énergies alternatives, Paris (FR)

(21) Appl. No.: 18/067,853

(22) Filed: Dec. 19, 2022

(30) Foreign Application Priority Data
Dec. 21, 2021 (FR) 21 14117

(51) Int. Cl. H10N 30/40; H10N 30/80; H02M 3/335

(52) U.S. Cl. CPC H10N 30/40; H10N 30/804; H02M 3/33569

(57) ABSTRACT

The electrical energy conversion system comprises:
a converter including E first switching assembly or assemblies, each associated with an input voltage and including two first switches; N second switching assembly or assemblies, each associated with an output voltage and including two second switches; and at least one piezoelectric assembly connected to a switch; E>1, N>1;
a control device configured for controlling, during a resonance cycle, a switching of the switches so as to alternate phases at constant voltage and phases at constant load across said piezoelectric assembly or assemblies.

The converter comprising an electrical transformer having a primary winding connected to a first switching assembly and a secondary winding connected to a second switching assembly, and each piezoelectric assembly being connected between a switch and a winding.

### CROSS-REFERENCE TO RELATED APPLICATIONS

This application is a U.S. non-provisional application claiming the benefit of French Application No. 21 14117, filed on Dec. 21, 2021, which is incorporated herein by reference in its entirety.

### FIELD

An electronic electrical energy conversion system apt to convert one or a plurality of input voltages into one or a plurality of output voltages, the conversion system comprising an electrical energy converter configured to deliver N separate output voltages from E separate input voltages, E and N each being an integer greater than or equal to 1, the converter including E first switching assembly or assemblies, each associated with a respective input voltage and including at least two first switches, each first switch being connected to a terminal for applying the respective input voltage; N second switching assembly or assemblies, each associated with a respective output voltage and including at least two second switches, each second switch being connected to a terminal for supplying the respective output voltage; and at least one piezoelectric assembly, each connected to one of the first and second switches, and including at least one piezoelectric element.

The conversion system further comprises an electronic control device for the electrical energy converter, the electronic control device being configured for controlling, during a respective resonance cycle of the at least one piezoelectric assembly, a switching of each of the first and second switches so as to alternate phases at a substantially constant voltage across the piezoelectric assembly or assemblies and phases at a substantially constant load across said piezoelectric assembly or assemblies.

The invention relates to the field of electronic systems for converting electrical energy, in particular systems including a piezoelectric element, in particular systems for converting electrical current i.e. DC-DC (direct current-direct current) conversion systems, and AC-DC (alternating current-direct current) conversion systems.

### BACKGROUND

An electrical energy converter of the aforementioned type is known from documents FIR 3 086 471 A1 and FR 3 086 472 A1 as well as from the thesis manuscript “Convertisseurs DC-DC piézoélectrique avec stockage provisoire d'énergie sous forme mécanique”[DC-DC piezoelectric converters using transient mechanical energy storage] by Benjamin POLLET, visible on the FIG. 20 of the documents FR 3 086 471 A1 and FR 3 086 472 A1, and of the FIG. 4.15 of the above-mentioned thesis manuscript.

The switches of the first and second switching bridges are cyclically controlled at the main oscillation frequency of the piezoelectric assemblies around the preselected resonance mode thereof with, between each closing of the switches, a phase wherein the piezoelectric assembly or assemblies are in open circuit via the opening of at least one switch. The closing of each switch advantageously takes place at a voltage approximately zero at the terminals thereof, and in all cases, the closing of a switch never generates a significant variation in voltage across the piezoelectric assembly or assemblies (less than 20%, and advantageously less than 10% of the input voltage Vᵢₙ or of the output voltage Vₒᵤₜ).

Under steady state conditions, a control cycle typically includes six distinct successive phases, namely three phases at a substantially constant voltage across each piezoelectric element and three phases at a substantially constant load across said piezoelectric element, alternating between phases at substantially constant voltage and phases at substantially constant load.

As indicated in document FR 3 086 471 A1 or in the thesis manuscript, one advantage of using two piezoelectric elements is that the output voltage is thus isolated from the input voltage, without any necessity to use a transformer.

The isolation is capacitive and is thus not achieved with a transformer which is a source of losses, but by the fact that the impedance of the piezoelectric resonator is very high at low frequency and blocks any low frequency voltage propagation from the input to the output and vice versa, in particular the possible common mode component equal to half the sum of the potentials at the terminals supplying the output voltage minus half the sum of the potentials at the terminals where the input voltage is applied. In fact, each piezoelectric element is modeled in the form of a capacitor and a resonant branch connected in parallel to the capacitor, the capacitance of said capacitor being called parallel capacitance, or reference capacitance, and denoted by C₀. A low frequency signal such as a 50/60 Hz signal will then be filtered by the high impedance (e.g. 3.1 MΩ for Cₒ=1 nF at 50 Hz) of each of the blocked capacitances of the two piezoelectric resonators thus creating isolation between the input and output parts of the converter.

Such advantage is present even compared with a piezoelectrical transformer, wherein all the energy supplied to the primary not completely transmitted to the secondary and the primary has, in addition, to set in motion a greater mass, namely the mass of the primary plus the mass of the secondary, which leads to losses.

However, the operation of such a converter is not optimal.

### SUMMARY

The goal of the invention is then to propose a conversion system comprising an electrical energy converter with at least one piezoelectric assembly, and a control device for the electrical energy converter, the system leading to a better operation of the converter.

To this end, the subject matter of the invention relates to an electronic electrical energy conversion system apt to convert one or a plurality of input voltages into one or a plurality of output voltages, the conversion system comprising:
an electrical energy converter configured for delivering N separate output voltage(s) from E distinct input voltage(s), where E and N are each an integer greater than or equal to 1, the converter comprising:
   E first switching assembly or assemblies, each associated with a respective input voltage and including at least two first switches, each first switch being connected to an application terminal of the respective input voltage;
   N second switching assembly or assemblies, each associated with a respective output voltage and including at least two second switches, each second switch being connected to a terminal for supplying the respective output voltage;
   at least one piezoelectric assembly, each being connected to one of the first and second switches, and including at least one piezoelectric element;
an electronic control device for the electrical energy converter, the electronic control device being configured for controlling, during a respective resonance cycle of the piezoelectric assembly or assemblies, a switching of each of the first and second switches so as to alternate phases of substantially constant voltage across the one or a plurality of piezoelectric assemblies and phases of substantially constant load across the one or a plurality of piezoelectric assemblies,

the converter further comprising an electrical transformer including at least one primary winding and at least one secondary winding, each primary winding being connected to a first switching assembly, each secondary winding being connected to a second switching assembly, and each piezoelectric assembly being connected between a respective switch and a respective winding.

With the energy conversion system according to the invention, the electrical transformer provides much higher conversion ratios than with the prior art conversion system, due to the conversion ratio between the secondary and primary windings, the value of the voltage during at least one phase with substantially constant voltage across the piezoelectric assembly or assemblies, i.e. the value of at least one voltage step, then dependent on a respective output voltage multiplied by said transformation ratio.

The electrical transformer associated with the piezoelectric assembly or assemblies further makes it possible to provide a plurality of successive levels of isolation, and e.g. to offer better isolation for critical systems.

A person skilled in the art will further observe that there is a complementarity between the two isolations. In the event of a faulty control or switch, at the primary or at the secondary, the primary or the secondary winding of the electrical transformer could be on the path of a short circuit, but due to the piezoelectric assembly or assemblies which block the low frequency components, such short circuit is naturally open, which prevents the heating of the electrical transformer and the failure of the transformer, which could, in addition, generate electrical risks for the user.

Furthermore, the use of two different types of isolation enhances isolation and safety, in the sense that two defects of a different nature would be required for generating a risk of loss of isolation, which is less likely than two defects of the same nature which could appear at the same time following the same type of stress (T°, humidity, etc.).

Moreover, the addition of a piezoelectric isolation is likely to make it possible to alleviate constraints weighing on the electrical transformer, such as the distance between primary and secondary turns, or even the thickness of varnish; and thus to gain in cost and/or efficiency.

Preferentially, the arrangement of at least one piezoelectric assembly upstream of the electrical transformer makes it possible to reduce, or even eliminate, the possible DC component across the primary winding of the electrical transformer, and then to further improve the operation thereof.

A person skilled in the art would observe that an electrical transformer alone, without being combined with one or a plurality of piezoelectric assemblies, can provide only one set voltage ratio between the input and the output. In order to be able to adjust the output voltage freely, it is possible to add an inductive element (LLC converter, dual bridge).

Nevertheless, the conversion system according to the invention combining with the electrical transformer at least one piezoelectric assembly has the advantage of having less losses (higher quality factor) and of being more compact (higher energy density which can be stored per unit volume) and also to be able to withstand a direct voltage component.

According to other advantageous aspects of the invention, the electronic electrical energy conversion system comprises one or a plurality of the following features, taken individually or according to all technically possible combinations:
each piezoelectric assembly is connected between a first switch and a primary winding or between a second switch and a secondary winding;
each winding is connected to at least one piezoelectric assembly or has between the ends thereof, a voltage of substantially zero mean value over a respective resonance cycle, the control device then being configured for controlling the switches of the switching assembly connected to said winding so as to obtain said voltage of substantially zero mean value;
the converter comprises a plurality of piezoelectric assemblies, and each winding is connected to at least one piezoelectric assembly;
the converter comprises a single piezoelectric assembly connected to a respective winding, and the or each other winding has between the ends thereof, a voltage of substantially zero mean value over a respective resonance cycle;
at least one first switching assembly is in the form of a first switching bridge including at least one first switching branch, each first switching branch being connected between two terminals for applying a respective input voltage and including at least two first switches connected in series and connected to each other at a first midpoint;

each first switching assembly preferentially being in the form of a respective first switching bridge;
at least one first switching assembly comprises two first switching branches;

each first switching assembly preferentially including two first switching branches;
a piezoelectric assembly is connected between a first midpoint and a respective primary winding;
at least one second switching assembly is in the form of a second switching bridge including at least one second switching branch, each second switching branch being connected between two terminals for supplying a respective output voltage and including at least two second switches connected in series and connected to each other at a second midpoint;

each second switching assembly is preferentially in the form of a respective second switching bridge;
at least one second switching assembly includes two second switching branches;

each second switching assembly preferentially comprises two second switching branches;
a piezoelectric assembly is connected between a second midpoint and a respective secondary winding;
a winding has, between the ends thereof, at least one intermediate point connected to a respective switching assembly or to a respective terminal for applying an input voltage or supplying an output voltage;
the converter comprises a pair of piezoelectric assemblies connected to the same respective winding, and in addition, a supplementary switch directly connected between ends of said pair of piezoelectric assemblies, said ends directly connected to each other via the supplementary switch, being connected to the same respective switching assembly;
the converter comprises a pair of piezoelectric assemblies connected to the same respective winding, and in addition a switching-aid circuit connected between ends of said pair of piezoelectric assemblies, said ends connected to each other via the switching-aid circuit, being connected to the same respective switching assembly, the switching-aid circuit being configured, via the flow of a previously received current, for discharging a parasitic capacitance of at least one switch of the respective switching assembly to which same is connected, and respectively charge at least one parasitic capacitance of another switch of said switching assembly;
the switching-aid circuit includes an element selected from the group consisting of: an inductor; a first assembly consisting of an inductor and a diode connected in series; a second assembly consisting of an inductor and a capacitor connected in series; and an additional piezoelectric element;
the switching-aid circuit preferentially consisting of an element selected from said group;

the inductor being preferentially still in the form of a parasitic inductor of the respective winding to which the pair of piezoelectric assemblies is connected;
the electrical transformer being an air transformer or a magnetic transformer, the magnetic transformer further including a magnetic core, each winding then being arranged around the core;

the electrical transformer being e.g. an autotransformer;
the electrical energy converter being configured for delivering a plurality of distinct output voltages and including a plurality of second switching assemblies, where N is an integer greater than or equal to 2; and
the electric energy converter being configured for converting a plurality of distinct input voltages and having a plurality of first switching assemblies, E being an integer greater than or equal to 2.

### BRIEF DESCRIPTION OF THE DRAWINGS

Such features and advantages of the invention will become clearer upon reading the following description, given only as a non-limiting example, and made with reference to the enclosed drawings, wherein:

FIG. 1 is a schematic representation of an electronic system for converting electrical energy according to the invention, comprising an electrical energy converter and an electronic device for controlling said converter, the converter being configured for delivering N output voltage(s) from E input voltage(s), and including E first switching assembly or assemblies, each associated with a respective input voltage and including at least two first switches, each first switch being connected to a terminal for applying the respective input voltage; N second switching assembly or assemblies, each associated with a respective output voltage and including at least two second switches, each second switch being connected to a terminal for supplying the respective output voltage; at least one piezoelectric assembly, each connected to one of the first and second switches; and further, an electrical transformer including at least one primary winding and at least one secondary winding, each primary winding being connected to a first switching assembly, each secondary winding being connected to a second switching assembly, and each piezoelectric assembly being connected between a respective switch and a respective winding;

E and N herein being each equal to 1, the first switching assembly being in the form of a first bridge with two first branches each including two first switches, the second switching assembly being in the form of a second bridge with two second branches each including two second switches, and the converter including four piezoelectric assemblies, each being connected to a midpoint of a respective branch;

FIG. 2 is a view similar to the view shown in FIG. 1, with two piezoelectric assemblies, each being connected to a midpoint of a respective first branch;

FIG. 3 is a view similar to the view shown in FIG. 1, with only one piezoelectric assembly connected to a midpoint of a respective first branch;

FIG. 4 is a view similar to the view shown in FIG. 1, with four piezoelectric assemblies, wherein the first switching assembly includes a single first branch with two first switches, and with a piezoelectric assembly at the primary, then connected to the midpoint of the first branch, and the other piezoelectric assembly connected to a respective terminal for applying the input voltage;

FIG. 5 is a view similar to the view shown in FIG. 4, with two piezoelectric assemblies, one piezoelectric assembly being connected to the midpoint of the first branch, and the other piezoelectric assembly being connected to a midpoint of a respective second branch;

FIG. 6 is a view similar to the view shown in FIG. 4, with a single piezoelectric assembly connected to the midpoint of the first branch;

FIG. 7 is a view similar to the view shown in FIG. 1, with two piezoelectric assemblies, wherein the first switching assembly includes a single first branch with two first switches, and the second switching assembly includes only one second branch with two second switches; one piezoelectric assembly being connected to the midpoint of the first branch, and the other piezoelectric assembly being connected to a respective terminal for supplying an output voltage;

FIG. 8 is a view similar to the view shown in FIG. 7, with a piezoelectric assembly connected to the midpoint of the first branch, and the other piezoelectric assembly connected to the midpoint of the second branch;

FIG. 9 is a view similar to the view shown in FIG. 8, with a single piezoelectric assembly, connected to a respective terminal for applying the input voltage, and where the secondary winding includes, between the ends thereof, an intermediate point connected to a respective terminal for supplying the output voltage;

FIG. 10 is a view similar to the view shown in FIG. 9, where E is equal to 1 and N is equal to 3; where the secondary winding includes, between the ends thereof, three intermediate points each connected to a respective terminal for supplying a respective output voltage or to a respective second switching assembly;

FIG. 11 is a view similar to the view shown in FIG. 1, where E is equal to 2 and N is equal to 1; with two piezoelectric assemblies, one piezoelectric assembly being connected to the midpoint of a respective first branch associated with one of the input voltages, and the other piezoelectric assembly being connected to a midpoint of a respective second branch;

FIG. 12 is a view similar to the view shown in FIG. 1, where E is equal to 1 and N is equal to 2; with two piezoelectric assemblies, each being connected to a midpoint of a respective second branch;

FIG. 13 is a view similar to the view shown in FIG. 2, according to a supplementary aspect wherein the converter further comprises a switching-aid circuit connected between the midpoints of the first branches, i.e. between the ends of the two piezoelectric assemblies which are not connected to the primary winding;

FIG. 14 is a schematic representation of the different types of switching-aid circuits; and

FIG. 15 is a view similar to the view shown in FIG. 2, according to a supplementary aspect wherein the converter further comprises a supplementary switch directly connected between the midpoints of the first branches, i.e. between the ends of the two piezoelectric assemblies which are not connected to the primary winding.

### DETAILED DESCRIPTION

The expression “substantially equal to” defines a relation of equality within plus or minus 10%, preferentially within plus or minus 5%.

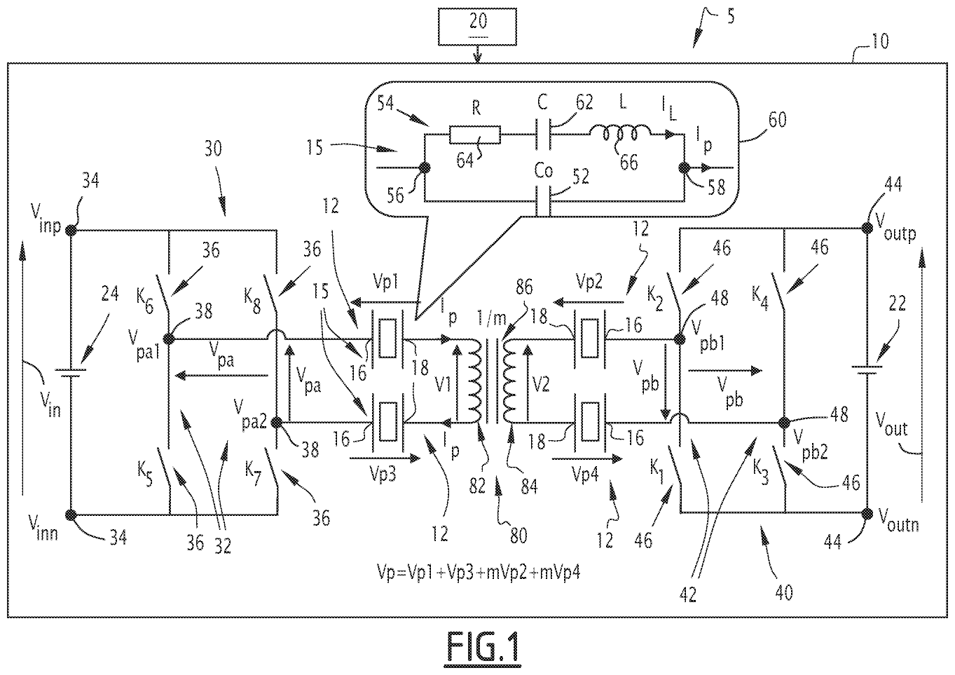

In FIG. 1, an electronic electrical energy conversion system 5 comprises an electrical energy converter 10 including at least one piezoelectric assembly 12 with at least one piezoelectric element 15, a plurality of switches K₁, K₂, K₃, K₄, K₅, K₆, K₇, K₈ apt to be controlled so as to alternate phases at substantially constant voltage across the terminals of the piezoelectric assembly or assemblies 12 and phases at substantially constant load across the terminals of the piezoelectric assembly or assemblies 12; and an electronic device 20 for controlling the electrical energy converter 10. Each piezoelectric assembly 12 includes a first end 16 and a second end 18.

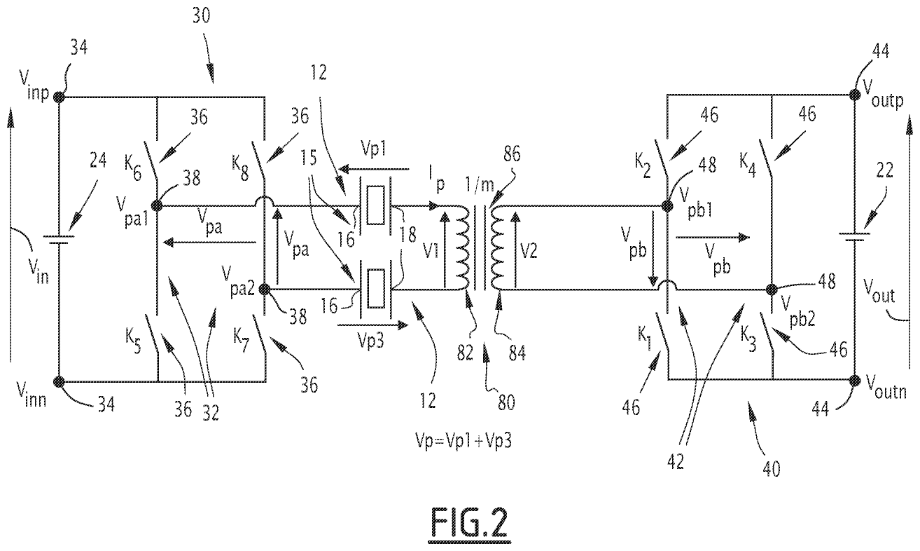

For the sake of simplifying the drawings, the rectangle schematically delimiting the electrical energy converter 10 and the electronic control device 20 are shown only in FIG. 1, and only the contents of the converter 10 is then shown in FIGS. 2 to 13 and 15.

The electronic electrical energy conversion system 5 is typically a DC electrical energy conversion system, such as a DC-DC conversion system apt to convert a first DC electrical energy or voltage received at the input into a second DC electrical energy or voltage delivered at the output, or else an AC-DC conversion system apt to convert an AC electrical energy or voltage received at the input into a DC electrical energy or voltage delivered at the output of the conversion system 5.

When the electrical energy conversion system 5 is an AC-DC conversion system, the electrical energy conversion system 5 preferentially further comprises a voltage rectifier (not shown) connected to the input of the electrical energy converter 10 and apt to rectify the alternating electric voltage received at the input of the conversion system 5 so as to deliver a rectified electric voltage at the input of the converter 10, the electrical energy converter 10 being preferentially a DC-DC converter apt to convert a DC electrical energy or voltage into another electrical energy or DC voltage. The voltage rectifier is e.g. a rectifier bridge, such as a diode bridge. In a variant, the voltage rectifier is formed in part by switches of the converter 10. A DC electrical voltage means a voltage which varies slowly with respect to the rate of variation of the voltage across the piezoelectric assemblies. The voltage variations typically take place at a frequency at least 10 times lower than the mechanical oscillation frequency of the piezoelectric assembly or assemblies 12.

A person skilled in the art would observe that the different examples for the conversion system 5, whether it is a DC-DC conversion system or an AC-DC conversion system, are also presented in documents FR 3 086 471 A1 and FR 3 086 472 A1, in particular with reference to FIGS. 1 and 2.

The electrical energy converter 10 is preferentially a DC-DC converter. The purpose of the DC-DC converter is generally to regulate a supply voltage of a load 22 to a stable value, by being supplied by a power source 24 supplying a substantially DC voltage. The energy source 24 is e.g. a battery or a solar panel.

The electrical energy converter 10 is then configured for raising the value of the DC voltage between the input thereof and output thereof and is then also called a step-up DC-DC converter; or is configured to lower the value of the DC voltage between the input thereof and the output thereof, and is then called a step-down DC-DC converter.

The electric energy converter 10 is configured for delivering N distinct output voltage(s) from E distinct input voltage(s), E and N each being an integer greater than or equal to 1.

In the examples shown in FIGS. 1 to 9, 13 and 15, the electrical energy converter 10 is configured for delivering an output voltage denoted by Vₒᵤₜ, from an input voltage denoted by Vᵢₙ, the number E of input voltage(s) and the number N of output voltage(s) being then each equal to 1.

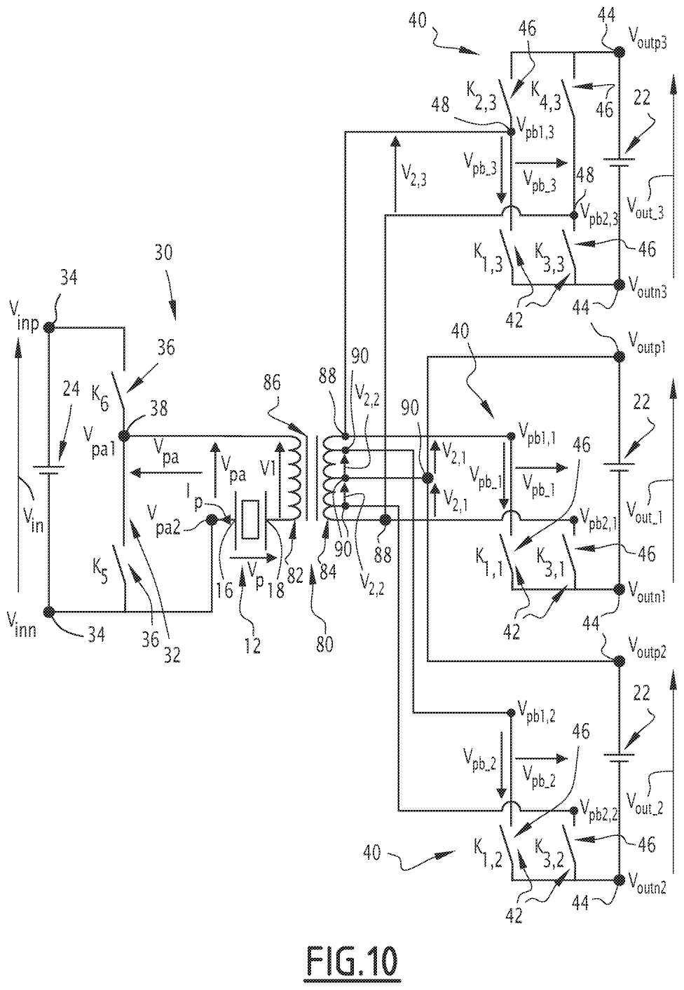

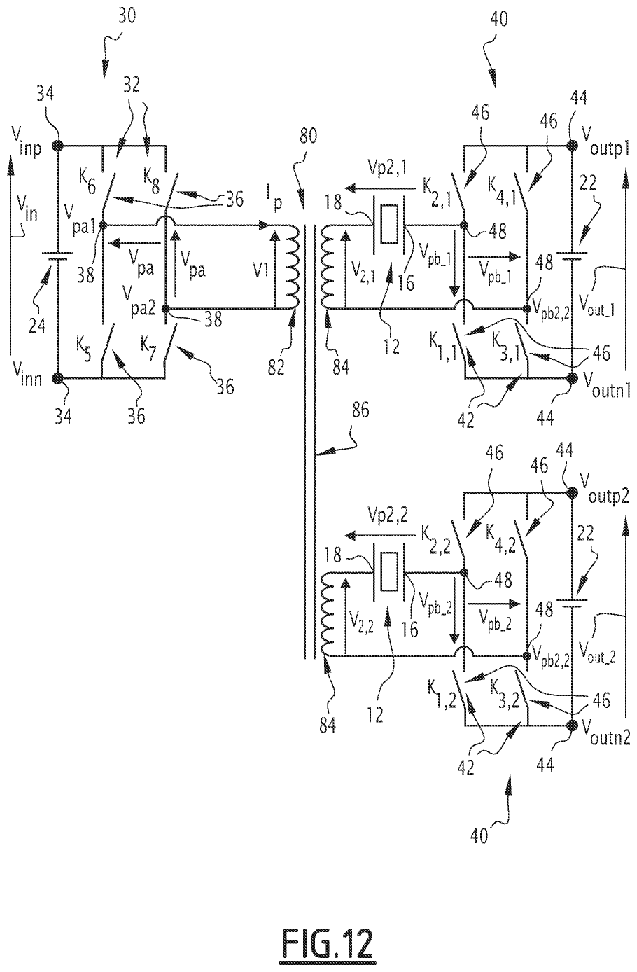

In the examples shown in FIGS. 10 and 12, the electrical energy converter 10 is configured for delivering a plurality of distinct output voltages denoted by V_{out_j}, where j is an integer index comprised between 1 and N, from the input voltage Vᵢₙ, the number N of distinct output voltages then being greater than 1, in particular equal to 3 in the example shown in FIG. 10, and to 2 in the example shown in FIG. 12. According to said example, the converter 10 is typically connected to a plurality of loads 22, as shown in FIGS. 10 and 12.

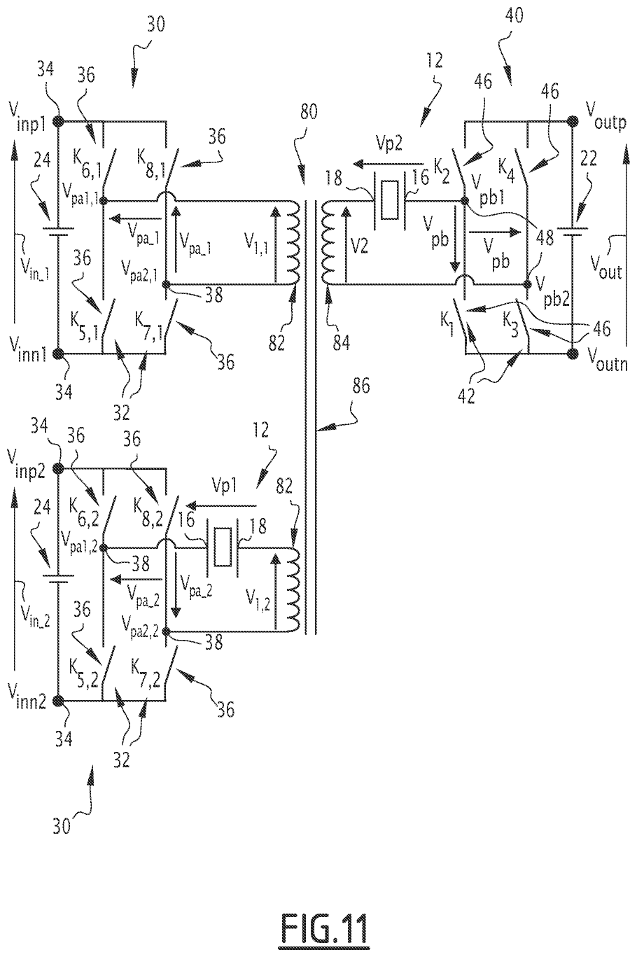

In the example shown in FIG. 11, the electrical energy converter 10 is configured for delivering an output voltage denoted by Vₒᵤₜ, from a plurality of distinct input voltages denoted by V_{in_k}, where k is an integer index comprised between 1 and E, the number E of distinct input voltages then being greater than 1, in particular equal to 2 in the example shown in FIG. 11. According to said example, the converter 10 is typically connected to a plurality of sources 24, as shown in FIG. 11.

The electrical energy converter 10 includes one or a plurality of piezoelectric assemblies 12 each formed of one or a plurality of piezoelectric elements 15, and the control device 20 is configured for operating the piezoelectric material of the piezoelectric elements 15 at the resonance thereof in order to exploit phases of load transfer which make it possible to dispense with the use of an inductive element, while regulating the output voltage while maintaining the resonance of the piezoelectric material, i.e. with repeated switching cycles at an operating frequency which is dependent on the resonance frequency of the piezoelectric elements 15, and adjusting the times between the respective commutations within the resonance cycle.

Under steady state conditions, the piezoelectric assembly or assemblies 12 exchange a load and a substantially zero power over a resonance cycle, except for losses. In other words, each piezoelectric assembly 12 gives back energy and load over a period substantially as much as it receives. Two operating conditions then apply to the steady state, namely the load balance and the energy balance over a resonance period. Even if during the transients (start, variation of the voltage steps, change of the output current), said balance is not achieved, it has to be nevertheless possible to achieve the balance under steady state conditions. The above imposes in particular, a certain arrangement of the voltage steps during the resonance period. E.g. for an operation with three voltage steps, the two extreme voltage steps are controlled during a half-period of a given polarity of a current I_{L} flowing through the piezoelectric elements 15, and the intermediate voltage step is controlled during the other half-period of opposite polarity of the current I_{L} flowing through the piezoelectric elements 15.

As is known per se, the mechanical oscillation of the piezoelectric elements 15 is approximately sinusoidal. The total mechanical deformation of the piezoelectric elements 15 is the sum of elementary mechanical deformations of each of the piezoelectric elements 15.

An increase or decrease in stored energy over a period leads to an increase or decrease in oscillation amplitude, respectively. Moreover, during a phase with a substantially constant load across the piezoelectric assemblies 12, i.e. when the piezoelectric elements 15 are placed in a substantially open electrical circuit, with a small exchange of electrical loads between the piezoelectric elements 15 and the outside, an increase in the amplitude of the oscillations leads to an increase in the rate of variation of the voltage Vₚ across the piezoelectric assemblies 12, and during a phase with a substantially constant voltage across the piezoelectric assemblies 12, such increase in oscillation amplitude leads to an increase in the current I_{L} flowing through the piezoelectric elements 15.

A substantially constant load refers to an exchange of a load with the outside which is less than 10% of the load which would have been exchanged with the outside if the voltage would have been kept constant. In other words, “substantially constant load” refers to a load variation of less than 10% of the load which would have been exchanged with the outside of the piezoelectric assemblies 12 if the voltage across the piezoelectric assemblies 12 would have been kept constant over the time period considered.

Substantially an open electrical circuit refers to a circuit the possible leakage current of which leads to a variation in the load of the piezoelectric assemblies 12 of less than 10% of the load which would have been exchanged with the outside of the piezoelectric assemblies 12 if the voltage across the piezoelectric assemblies 12 would have been kept constant over the length of time considered.

“Substantially constant voltage” refers to a voltage variation of less than 20%, preferentially less than 10%, of the input or output voltage of the converter 10. As an example, if the input voltage of the converter 10 is equal to 100 V, then the voltage variation during each phase with substantially constant voltage, i.e. at each substantially constant voltage step, is less than 20% of said voltage, i.e. less than 20 V; preferentially less than 10% of said voltage, i.e. less than 10 V. Each phase with a substantially constant voltage is also called a voltage step.

The converter 10 then includes a plurality of switches K₁, K₂, K₃, K₄, K₅, K₆, K₇, K₈ visible at least in part in FIGS. 1 to 9, 13 and 15, K_{i,m} visible on FIGS. 10 to 12 (where i is an integer index representing a switch identifier, typically comprised between 1 and 8 in the examples shown in FIGS. 10 to 12, and m is an integer index representing an identifier of an input voltage, or of an output voltage, typically comprised between 1 and 3 in the examples shown in FIGS. 10 to 12), apt to be controlled so as to alternate phases with a substantially constant voltage and phases with a substantially constant load across the piezoelectric assemblies 12, within periods of substantially constant length of time corresponding to the operating frequency of the converter 10, depending on the resonant frequency, also called the natural frequency of the piezoelectric elements 15. The phases with a substantially constant load make it possible, in the steady state, to switch from one constant voltage to another and to close the switches which have to be closed when the voltage across same is preferentially zero in order to have a so-called zero-voltage switching.

The converter 10 comprises E first switching assembly or assemblies 30, each being associated with a respective input voltage Vᵢₙ, V_{in_k} and including at least two first switches 36, each first switch 36 being connected to a terminal 34 for applying the respective input voltage Vᵢₙ, V_{in_k}, where E is the number of separate input voltage(s) Vᵢₙ, V_{in_k}, E being greater than or equal to 1.

In the examples shown in FIGS. 1 to 13 and 15, the first switches 36 correspond to the switches K₅, K₆, K₇, K₈ visible at least in part in FIGS. 1 to 9, 13 and 15, or to the switches K_{i,m} visible in FIGS. 10 to 12, with i comprised between 5 and 8.

In the examples shown in FIGS. 1 to 10, 12, 13 and 15, where E is equal to 1, the converter 10 comprises only one first switching assembly 30 associated with the input voltage Vᵢₙ.

In the example shown in FIG. 11, where E is equal to 2, the converter 10 comprises two first switching assemblies 30, each being associated with a respective input voltage V_{in_1}, V_{in_2}.

Optionally, at least one first switching assembly 30 is in the form of a first switching bridge including at least one first switching branch 32, each first switching branch 32 being connected between two terminals 34 for applying a respective input voltage Vᵢₙ, V_{in_k} and including at least two first switches 36 connected in series and connected together at a first midpoint 38. Each first switching branch 32 preferentially consists of the two first switches 36.

According to such optional addition, each first switching assembly 30 is preferentially in the form of a respective first switching bridge, and then includes at least one first switching branch 32.

As an optional addition, at least one first switching assembly 30 includes two first switching branches 32. According to such optional addition, each first switching assembly 30 preferentially includes two first switching branches 32.

In the examples shown in FIGS. 1 to 3, 11 to 13 and 15, the or each first switching assembly 30 includes two first switching branches 32. In the examples shown in FIGS. 1 to 3, 11 to 13 and 15, the or each first switching assembly 30 preferentially consists of the two first switching branches 32.

In the examples shown in FIGS. 1 to 3, 12, 13 and 15, the first two switches 36 are denoted by K₅, K₆ for one of the first two switching branches 32, and K₇, K₈, respectively, for the other of the first two switching branches 32. In the example shown in FIG. 11, the first two switches 36 are denoted by K_{5,k}, K_{6,k} for one of the first two switching branches 32, and K_{7,k}, K_{8,k} for the other of the first two switching branches 32, respectively, where k is the integer index for the input voltage, comprised between 1 and E.

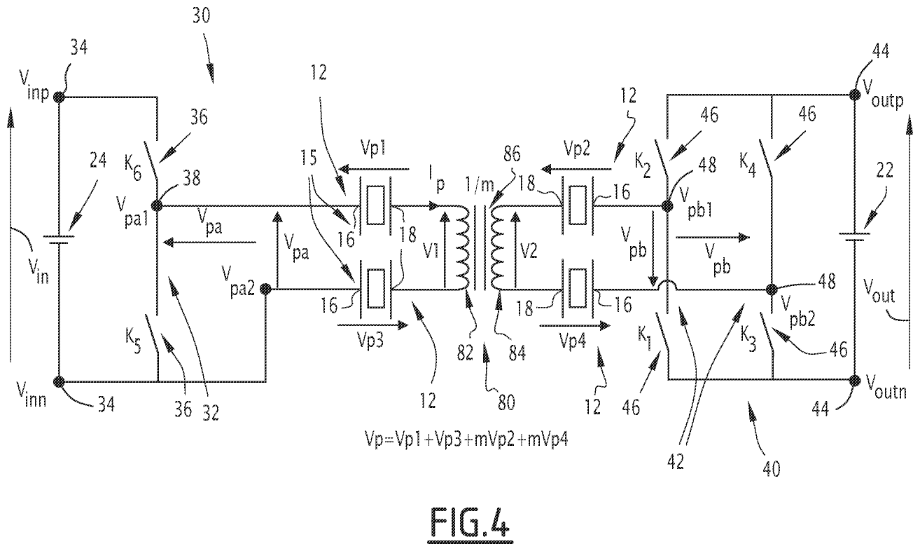

In the examples shown in FIGS. 4 to 10, the first switching assembly 30 includes only one first switching branch 32. In the examples shown in FIGS. 4 to 10, the first switching assembly 30 preferentially consists of a single first switching branch 32. In said examples, the first two switches 36 are denoted by K₅, K₆ for the single first switching branch 32.

Of the two application terminals 34 of the input voltage Vᵢₙ, one has a lower potential, denoted by Vᵢₙₙ, and the other has a higher potential, denoted by Vᵢₙₚ.

When the electrical energy converter 10 is configured for receiving a plurality of distinct input voltages V_{in_k}, as in the example shown in FIG. 11, same comprises, for each respective input voltage V_{in_k}, a respective first switching assembly 30. In the example shown in FIG. 11, the lower potentials of the input voltages V_{in_1}, V_{in_2} are denoted by Vᵢₙₙ₁, Vᵢₙₙ₂, respectively, and the upper potentials of the input voltages V_{in_1}, V_{in_2} are denoted by Vᵢₙₚ₁, Vᵢₙₚ₂, respectively.

The converter 10 comprises N second switching assembly or assemblies 40, each being associated with a respective output voltage Vₒᵤₜ, V_{out_j} and including at least two second switches 46, each second switch 46 being connected to a terminal 44 for supplying the respective output voltage Vₒᵤₜ, V_{out_j}, where N is the number of distinct output voltage(s) Vₒᵤₜ, V_{out_j}, N being greater than or equal to 1.

In the examples shown in FIGS. 1 to 13 and 15, the second switches 46 correspond to the switches K₁, K₂, K₃, K₄ visible at least in part in FIGS. 1 to 9, 13 and 15, or to the switches K_{i,m} visible in FIGS. 10 to 12, with i comprised between 1 and 4.

In the examples shown in FIGS. 1 to 9, 11, 13 and 15, where N is equal to 1, the converter 10 comprises only one second switching assembly 40 associated with the output voltage Vₒᵤₜ.

In the example shown in FIG. 10, where N is equal to 3, the converter 10 comprises three second switching assemblies 40, each being associated with a respective output voltage V_{out_1}, V_{out_2}, V_{out_3}, and in the example shown in FIG. 12, where N is equal to 2, the converter 10 comprises two second switching assemblies 40, each being associated with a respective output voltage V_{out_1}, V_{out_2}.

As an optional addition, at least one second switching assembly 40 is in the form of a second switching bridge including at least one second switching branch 42, each second switching branch 42 being connected between two terminals 44 for supplying a respective output voltage Vₒᵤₜ, V_{out_j} and including at least two second switches 46 connected in series and connected together at a second midpoint 48. Each second switching branch 32 preferentially consists of the two second switches 46.

According to said optional addition, each second switching assembly 40 is preferentially in the form of a respective second switching bridge, and then includes at least one second switching branch 42.

As an optional addition, at least one second switching assembly 40 includes two second switching branches 42. According to such optional addition, each second switching assembly 40 preferentially includes two second switching branches 42.

In the examples shown in FIGS. 1 to 6, 11 to 13 and 15, the or each second switching assembly 40 includes two second switching branches 42. In the examples shown in FIGS. 1 to 6, 11 to 13 and 15, the or each second switching assembly 40 preferentially consists of the two second switching branches 42.

In the examples shown in FIGS. 1 to 6, 11, 13 and 15, the two second switches 46 are denoted by K₁, K₂ for one of the two second switching branches 42, and K₃, K₄, respectively, for the other of the two second switching branches 42. In the example shown in FIG. 12, the two second switches 46 are denoted by K_{1,j}, K_{2,j} for one of the two second switching branches 42, and K_{3,j}, K_{4,j}, respectively, for the other of the two second switching branches 42, where j is the integer index for the output voltage, comprised between 1 and N.

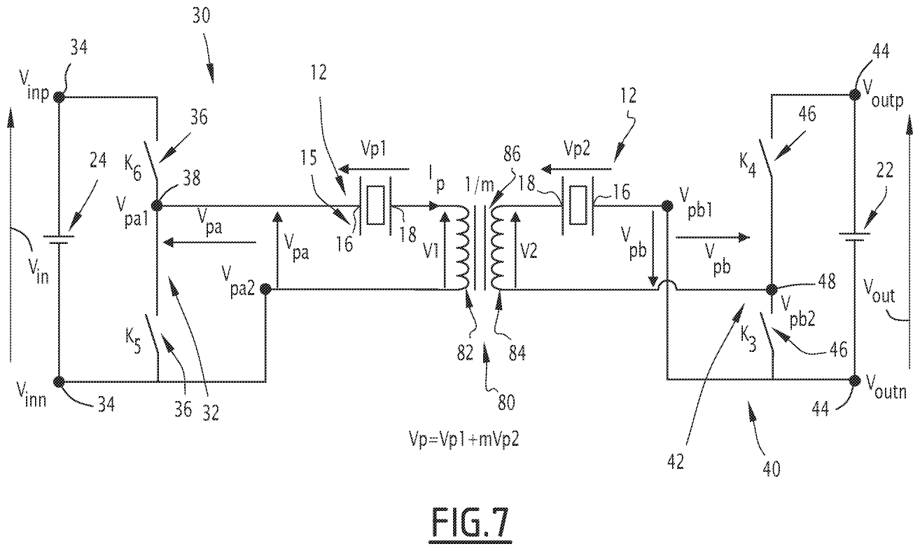

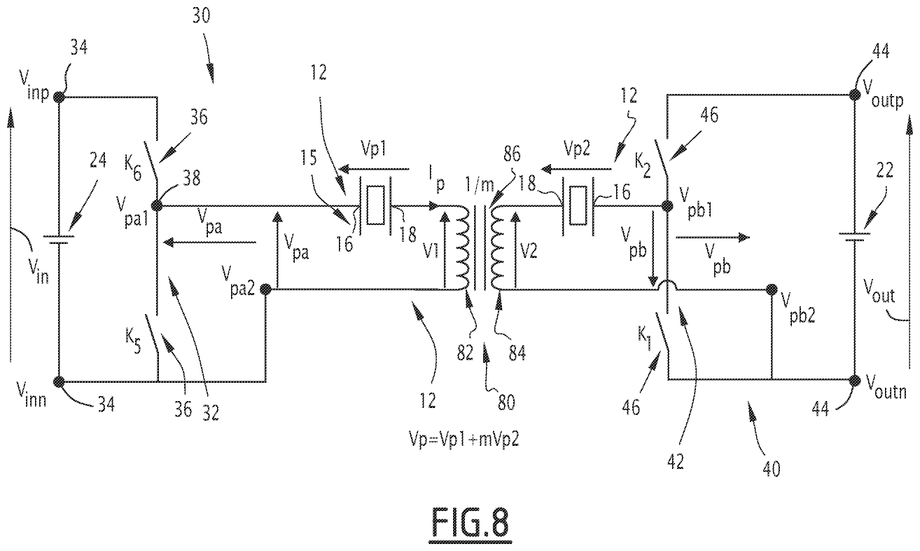

In the examples shown in FIGS. 7 and 8, the second switching assembly 40 includes only one second switching branch 42. In the examples shown in FIGS. 7 and 8, the second switching assembly 40 preferentially consists of a single second switching branch 42. In the example shown in FIG. 8, the two second switches 46 are denoted by K₁, K₂ for the single second switching branch 42. In the example shown in FIG. 7, the two second switches 46 are denoted by K₃, K₄ for the single second switching branch 42.

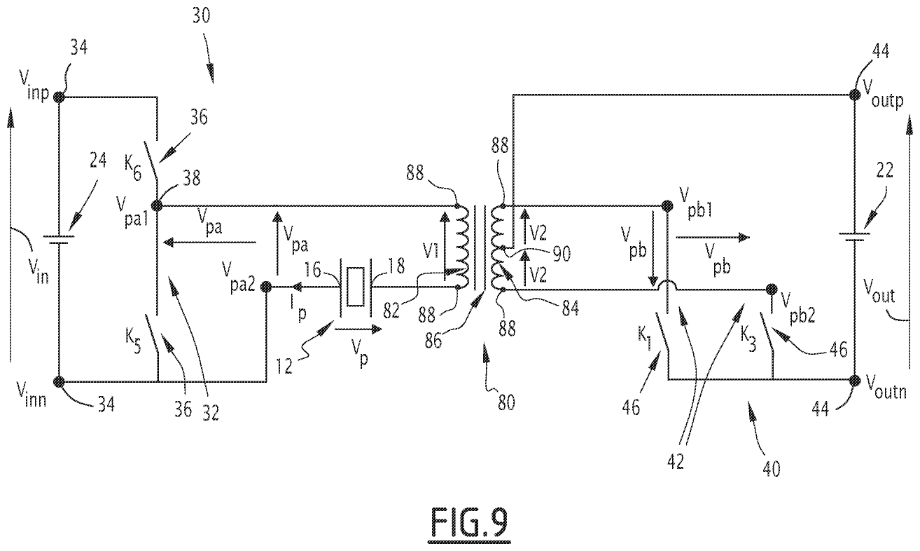

In the example shown in FIG. 9, the second switching assembly 40 includes two second switches 46 connected to the same output voltage supply terminal 44. In said example, the two second switches 46 are denoted by K₁, K₃.

In the example shown in FIG. 10, the converter 10 comprises three second switching assemblies 40, amongst which two second switching assemblies 40 each include two second switches 46 connected to the same output voltage supply terminal 44, said second switches 46 being denoted by K_{1,1}, K_{3,1,} and K_{1,2}, K_{3,2}, respectively. The other second switching assembly 40 includes two second switching branches 42, the two second switches 46 then being denoted by K_{1,3}, K_{2,3} for one of the two second switching branches 42, and K_{3,3}, K_{4,3} respectively, for the other of the two second switching branches 42, said other second switching assembly 40 being associated with the output voltage V_{out_3}, with the index j equal to 3.

Among the two supply terminals 44 of the output voltage Vₒᵤₜ, one has a lower potential denoted by Vₒᵤₜₙ, and the other has a higher potential denoted by Vₒᵤₜₚ.

When the electrical energy converter 10 is configured for delivering a plurality of distinct output voltages V_{out_j}, as in the examples shown in FIGS. 10 and 12, same comprises, for each respective output voltage V_{out_j}, a respective second switching assembly 40. In the examples shown in FIGS. 10 and 12, the lower potentials of the output voltages V_{out_1}, V_{out_2}, or even V_{out_3} (FIG. 10) are respectively denoted by Vₒᵤₜₙ₁, Vₒᵤₜₙ₂, Vₒᵤₜₙ₃, and the higher potentials of the output voltages V_{out_1}, V_{out_2}, or even V_{out_3} are denoted by Vₒᵤₜₚ₁, Vₒᵤₜₚ₂, Vₒᵤₜₚ₃, respectively.

According to the invention, the converter 10 further comprises an electrical transformer 80 including at least one primary winding 82 and at least one secondary winding 84, each primary winding 82 being connected to a first switching assembly 30, each secondary winding 84 being connected to a second switching assembly 40.

In general, the voltage at the terminals of the primary winding 82, also called the primary voltage, is denoted by V1, the voltage at the terminals of the secondary winding 84, also called the secondary voltage, is denoted by V2, and the transformation ratio m of the electrical transformer 80 is equal to the ratio of the voltage at the secondary V2 divided by the voltage at the primary V1. In other words, the voltage at the primary V1 is equal to m times the voltage at the secondary V2, according to the following equation:

V1=m·V2 [1]

where V2 is the voltage at the terminals of the secondary winding 84,

V1 represents the voltage at the terminals of the primary winding 82, and

m represents the transformation ratio of the electrical transformer 80.

In the example shown in FIG. 11, the electrical transformer 80 comprises two primary windings 82, the voltage at the terminals of a primary winding 82 then being denoted by V1,1, and the voltage at the terminals of the other primary winding 82 being denoted by V1,2.

In the example shown in FIG. 12, the electrical transformer 80 includes two secondary windings 84, the voltage at the terminals of a secondary winding 84 then being denoted by V2,1, and that at the terminals of the other secondary winding 84 being denoted by V2,2.

The electrical transformer 80 is e.g. a magnetic transformer, and then further includes a magnetic core 86, each winding 82, 84 then being arranged around the magnetic core 86.

In a variant, the electrical transformer 80 is an air transformer, and does not then include a magnetic core. Such variant is particularly suitable when the electrical energy converter 10 works at high frequency, such as a frequency greater than 10 MHz.

The electrical transformer 80 is e.g. further an autotransformer, for which a part of the turns is shared between two windings, e.g. shared between the primary winding 82 and the secondary winding 84, or shared between two primary windings 82, or further shared between two secondary windings 84.

According to the invention, each piezoelectric assembly 12 is connected between a respective switch 36, 46 and a respective winding 82, 84. In other words, each piezoelectric assembly 12 is connected between a respective switching assembly 30, 40 and a respective winding 82, 84. By convention, each piezoelectric assembly 12 is connected by the first end 16 thereof to a respective switching assembly 30, 40, and by the second end 18 thereof to a respective winding 82, 84.

Each piezoelectric assembly 12 is connected between a first switch 36 and a primary winding 82 or is connected between a second switch 46 and a secondary winding 84.

As an optional addition, the converter 10 comprises at least one pair of piezoelectric assemblies 12 connected to the same respective winding 82, 84, as shown in the examples shown in FIGS. 1, 2, 4, 13 and 15.

In the examples shown in FIGS. 1 and 4, the converter 10 comprises two pairs of piezoelectric assemblies 12, a first pair of piezoelectric assemblies 12 being connected to the primary winding 82 and a second pair of piezoelectric assemblies 12 being connected to the secondary winding 84.

In the examples shown in FIGS. 2, 13 and 15, the converter 10 comprises a single pair of piezoelectric assemblies 12. In said examples, the pair of piezoelectric assemblies 12 is connected to the primary winding 82.

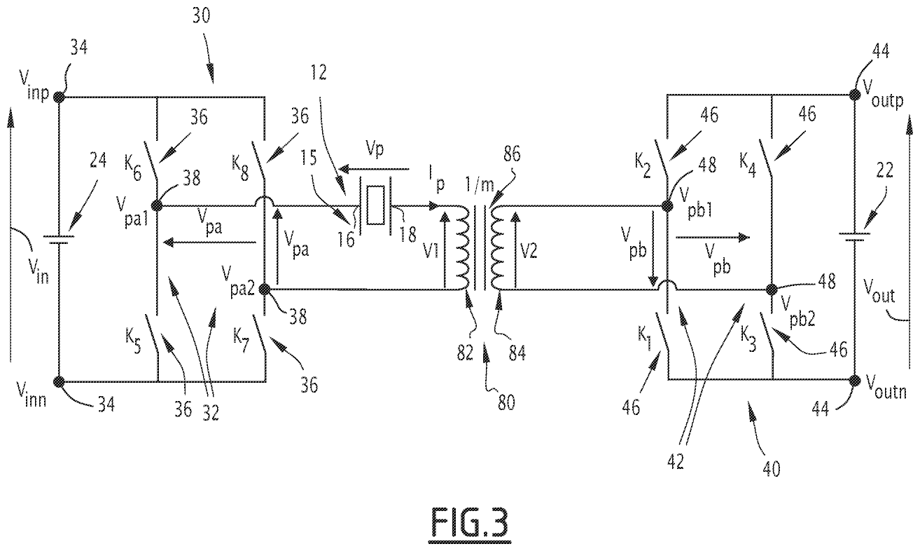

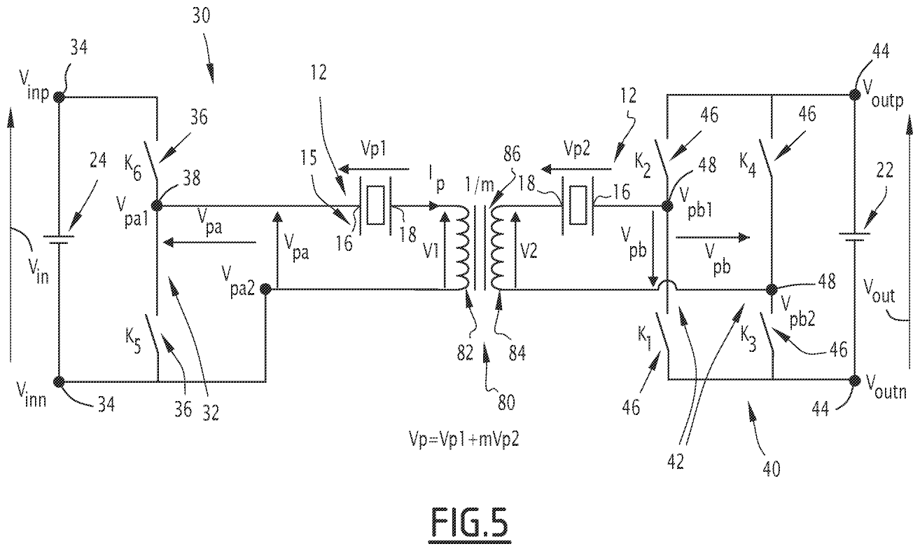

In the other examples shown in FIGS. 3 and 5 to 12, the converter 10 comprises at most one piezoelectric assembly 12 connected to each respective winding 82, 84. In the examples shown in FIGS. 3, 6, 9 and 10, the converter 10 comprises a single piezoelectric assembly 12 connected to the primary winding 82. In the examples shown in FIGS. 5, 7 and 8, the converter 10 comprises two piezoelectric assemblies 12, one being connected to the primary winding 82 and the other being connected to the secondary winding 84. In the example shown in FIG. 11, the converter 10 comprises two piezoelectric assemblies 12, one being connected to one of the two primary windings 82 and the other being connected to the secondary winding 84. In the example shown in FIG. 12, the converter 10 comprises two piezoelectric assemblies 12, each connected to a respective secondary winding 84.

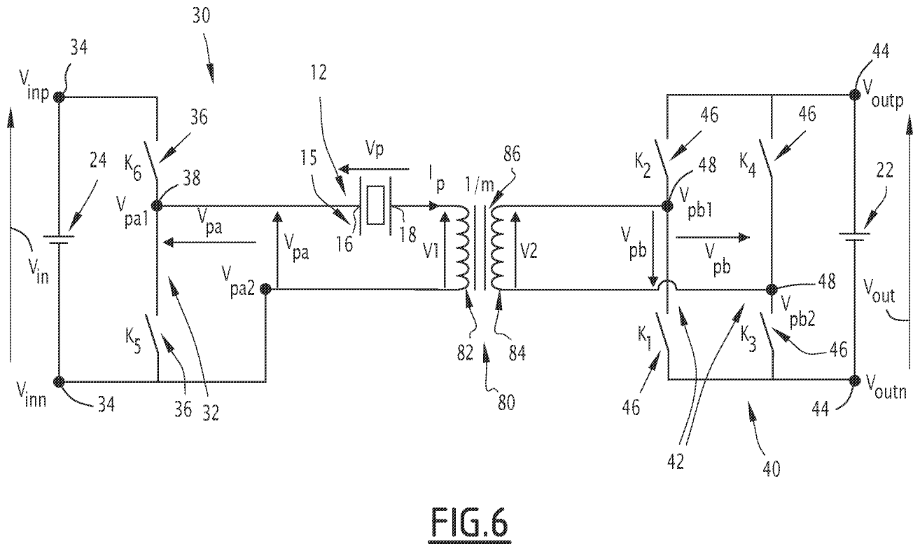

In the examples shown in FIGS. 1 to 3, 5, 6, 8, 11 to 13 and 15, each piezoelectric assembly 12 is connected between a respective midpoint 38, 48 and a respective winding 82, 84. In particular, in the examples shown in FIGS. 1, 2, 13 and 15, the piezoelectric assemblies 12 of each pair connected to the primary winding 82 are each connected between a respective first midpoint 38 and the primary winding 82. Furthermore, in the example shown in FIG. 1, the piezoelectric assemblies 12 of the pair connected to the secondary winding 84 are each connected between a respective second midpoint 48 and the secondary winding 84. In the examples shown in FIGS. 3 and 6, the single piezoelectric assembly 12 is connected between a respective first midpoint 38 and the primary winding 82. In the examples shown in FIGS. 5, 8 and 11, a piezoelectric assembly 12 is connected between a respective first midpoint 38 and the primary winding 82, and the other piezoelectric assembly 12 is connected between a respective second midpoint 48 and the secondary winding 84. In the example shown in FIG. 12, each piezoelectric assembly 12 is connected between a respective second midpoint 48 and a respective secondary winding 84.

In the example shown in FIG. 4, for the pair of piezoelectric assemblies 12 connected to the primary winding 82, a piezoelectric assembly 12 is connected between a respective midpoint 38 and the primary winding 82, and the other piezoelectric assembly 12 is connected between an input voltage application terminal 34 and the primary winding 82; and for the pair of piezoelectric assemblies 12 connected to the secondary winding 84, each piezoelectric assembly 12 is connected between a respective second midpoint 48 and the secondary winding 84.

In the example shown in FIG. 7, a piezoelectric assembly 12 is connected between a respective midpoint 38 and the primary winding 82, and the other piezoelectric assembly 12 is connected between an output voltage supply terminal 44 and the secondary winding 84.

In the examples shown in FIGS. 9 and 10, the single piezoelectric assembly 12 is connected between an input voltage application terminal 34 and the primary winding 82.

In addition, each winding 82, 84 is preferentially connected to at least one piezoelectric assembly 12 or has between the ends 88 thereof (referenced in FIGS. 9 and 10) a voltage with a substantially zero mean value over a respective resonance cycle, the control device 20 then being configured for controlling the switches 36 or 46 of the switching assembly 30 or 40 connected to said winding 82, 84 so as to obtain said voltage with a substantially zero mean value.

According to said addition, when the converter 10 comprises a plurality of piezoelectric assemblies 12, each winding 82, 84 is preferentially connected to at least one piezoelectric assembly 12. In other words, according to said addition and when the converter 10 comprises a plurality of piezoelectric assemblies 12, at least one piezoelectric assembly 12 is connected to the primary winding 82, and at least one other piezoelectric assembly 12 is connected to the secondary winding 84.

According to said addition, when the converter 10 comprises only one piezoelectric assembly 12 connected to a respective winding 82; 84, and the or each other winding 84; 82 has between the ends 88 thereof a voltage of substantially zero mean value over a respective resonance cycle.

Each piezoelectric assembly 12 comprises at least one piezoelectric element 15.

Preferentially, each piezoelectric assembly 12 is formed according to one of the constructions from the group consisting of: a single piezoelectric element 15; a plurality of piezoelectric elements 15 connected in series; a plurality of piezoelectric elements 15 connected in parallel; a piezoelectric element 15 and an auxiliary capacitor (not shown), connected in series; a piezoelectric element 15 and an auxiliary capacitor connected in parallel; and an arrangement of a plurality of parallel branches, each branch including one or a plurality of piezoelectric elements 15 connected in series or an auxiliary capacitor.

The auxiliary capacitor typically has a capacitance greater than, preferentially at least three times greater than, a reference capacitance C₀, as described hereinafter, of the piezoelectric element or elements 15.

As an optional addition, the or each pair of piezoelectric assemblies 12 share the same piezoelectric material, while having the electrodes of a respective piezoelectric assembly 12 distinct from the electrodes of the other piezoelectric assembly 12 of said pair. According to such optional addition, the pairs of electrodes of a respective piezoelectric assembly 12 and the electrodes of the other piezoelectric assembly 12, respectively, of said pair, cover distinct material surfaces. Furthermore, the electrodes of a respective piezoelectric assembly 12 cannot in such case directly induce a significant electric field in the part of the piezoelectric material belonging to the other piezoelectric assembly 12 of said pair. Further according to such optional addition, the capacitance between any one of the electrodes of a respective piezoelectric assembly 12 and any one of the electrodes of the other piezoelectric assembly 12 of said pair is negligible (at least 10 times smaller) compared with a reference capacitance C₀, as described hereinafter, of each of the assemblies 12, e.g. by not directly facing each other on both sides of the material. Such sharing of the same material makes it possible e.g. to facilitate the implementation of the pair of piezoelectric assemblies 12 (limitation of the number of parts, sharing of the means of fastening); and also to synchronize the vibration of the two piezoelectric assemblies 12, without however, there being a significant transfer of energy from one assembly 12 to the other (< 1/10^{th} of the output power).

The piezoelectric element 15 is known per se, and is typically modeled, close to the resonant mode used, in the form of a capacitor 52 and a resonant branch 54 connected in parallel with the capacitor 52, the capacitor 52 and the resonant branch 54 being connected between a first electrode 56 and a second electrode 58 of the piezoelectric element 15, as illustrated in the modeling of the piezoelectric element 15 as shown in a box 60 in FIG. 1. The resonant branch 54 is typically an RLC branch formed by a capacitor 62, a resistor 64 and an inductor 66 connected in series. The capacitance of the capacitor 52 connected in parallel with the resonant branch 54 is called parallel capacitance, or blocked capacitance, or reference capacitance, and denoted by C₀. The voltage across the piezoelectric element 15 then typically corresponds to the voltage across the capacitor 52.

In the present description, a so-called total piezoelectric voltage Vₚ is by convention the sum of each of the voltages across the piezoelectric assemblies 12 reduced to the voltage of the primary winding of the electrical transformer 80.

By convention, in the present description, the total piezoelectric voltage Vₚ represents the total voltage, seen from the primary side of the electrical transformer 80, of the piezoelectric assembly or assemblies 12 which act in series. Thus, the voltages across the piezoelectric assemblies 12 which are connected to the secondary winding 84 are multiplied by the transformation ratio m of the electrical transformer 80, when reduced to the voltage of the primary winding.

In the examples shown in FIGS. 1 and 4, the total piezoelectric voltage Vₚ then satisfies the following equation:

Vₚ=Vₚ₁+Vₚ₃+m·Vₚ₂+m·Vₚ₄ [2]

where Vₚ₁, Vₚ₃ represent the respective voltages across each of the piezoelectric assemblies 12 connected to the primary winding 82, and

Vₚ₂, Vₚ₄ represent the respective voltages across each of the piezoelectric assemblies 12 connected to the secondary winding 84.

Similarly, in the examples shown in FIGS. 2, 13 and 15, the total piezoelectric voltage Vₚ then satisfies the following equation:

Vₚ=Vₚ₁+Vₚ₃ [3]

where Vₚ₁, Vₚ₃ represent the respective voltages across each of the piezoelectric assemblies 12 connected to the primary winding 82.

In the examples shown in FIGS. 3, 6, 9 and 10, the total piezoelectric voltage Vₚ is equal to the voltage across the single piezoelectric assembly 12.

In the examples shown in FIGS. 5, 7 and 8, the total piezoelectric voltage Vₚ then satisfies the following equation:

Vₚ=Vₚ₁+m·Vₚ₂ [4]

where Vₚ₁ is the voltage across the piezoelectric assembly 12 connected to the primary winding 82, and

Vₚ₂ represents the voltage across the piezoelectric assembly 12 connected to the secondary winding 84.

In the example shown in FIG. 12, at two distinct output voltages V_{out_1}, V_{out_2}, each associated with a respective secondary winding 84, and a piezoelectric assembly 12 connected to each secondary winding 84, there are two distinct piezoelectric voltages, controlled independently of each other by the electronic control device 20, namely a first piezoelectric voltage V_{p_out1} and a second piezoelectric voltage V_{p_out2}.

In the example shown in FIG. 12, the first piezoelectric voltage V_{p_out1} satisfies the following equation:

V_{p_out1}=m1·V_{p2,1} [5]

where V_{p_out1} represents the first piezoelectric voltage, i.e. the piezoelectric voltage reduced to the voltage of the primary for the piezoelectric assembly 12 connected to the secondary winding 84 associated with the first output voltage V_{out_1},

V_{p2,1} represents the voltage across said piezoelectric assembly 12 connected to the secondary winding 84 associated with the first output voltage V_{out_1}, and

m1 is the transformation ratio between the primary winding 82 and the secondary winding 84 associated with the first output voltage V_{out_1}, satisfying the equation:

V1=m1·V2,1 [6]

where V2,1 represents the voltage at the terminals of said secondary winding 84 associated with the first output voltage V_{out_1},

V1 represents the voltage at the terminals of the primary winding 82, and

m1 represents said transformation ratio.

In the example shown in FIG. 12, the second piezoelectric voltage V_{p_out2} satisfies the following equation:

V_{p_out2}=m2·V_{p2,2} [7]

where V_{p_out2} represents the second piezoelectric voltage, i.e. the piezoelectric voltage reduced to the voltage of the primary for the piezoelectric assembly 12 connected to the secondary winding 84 associated with the second output voltage V_{out_2},

V_{p2,2} represents the voltage across said piezoelectric assembly 12 connected to the secondary winding 84 associated with the second output voltage V_{out_2}, and

M2 is the transformation ratio between the primary winding 82 and the secondary winding 84 associated with the second output voltage V_{out_2}, satisfying the equation:

V1=m2·V2,2 [8]

where V2,2 represents the voltage across said secondary winding 84 associated with the second output voltage V_{out_2},

V1 represents the voltage at the terminals of the primary winding 82, and

m2 represents said transformation ratio.

The first piezoelectric voltage V_{p_out1} thus makes it possible to manage the current exchanged with the first output voltage V_{out_1}, and the second piezoelectric voltage V_{p_out2} makes it possible to manage the current exchanged with the second output voltage V_{out_2}, independently between the first output voltage V_{out_1} and the second output voltage V_{out_2}, as well as between the respective currents associated with the distinct output voltages V_{out_1}, V_{out_2}.

Similarly, in the example shown in FIG. 11, with two distinct input voltages V_{in_1}, V_{in_2}, each associated with a respective primary winding 82, there are also two distinct piezoelectric voltages, controlled independently of one another by the electronic control device 20, Namely a first piezoelectric voltage V_{p_out1} and a second piezoelectric voltage V_{p_in2}.

In the example shown in FIG. 11, the first piezoelectric voltage V_{p_out1} satisfies the following equation:

V_{p_out1}=m1′·Vₚ₂ [9]

where V_{p_out1} represents the first piezoelectric voltage in said example, i.e. the piezoelectric voltage reduced to the voltage of the primary of the first input voltage V_{in_1}, for the piezoelectric assembly 12 connected to the secondary winding 84,

Vₚ₂ represents the voltage across said piezoelectric assembly 12 connected to the secondary winding 84, and

m1′ is the transformation ratio between the primary winding 82 associated with the first input voltage V_{in_1} and the secondary winding 84, satisfying the following equation:

V1,1=m1′·V2 [10]

where V2 is the voltage at the terminals of the secondary winding 84,

V1,1 represents the voltage at the terminals of said primary winding 82 associated with the first input voltage V_{in_1}, and

m1′ represents said transformation ratio.

In the example shown in FIG. 11, the transformation ratio between the primary winding 82 associated with the second input voltage V_{in_2} and the secondary winding 84 is denoted by m2′ and satisfies the equation:

V1,2=m2′·V2 [11]

where V2 is the voltage at the terminals of the secondary winding 84,

V1,2 represents the voltage at the terminals of said primary winding 82 associated with the second input voltage V_{in_2}, and

m2′ represents said transformation ratio.

In the example shown in FIG. 11, the second piezoelectric voltage V_{p_in2} satisfies the following equation:

V_{p_in2}=Vₚ₁ [12]

where V_{p_in2} represents the second piezoelectric voltage in the example shown in FIG. 11, i.e. the piezoelectric voltage at the primary for the piezoelectric assembly 12 connected to the primary winding 82 associated with the second input voltage V_{in_2}, and

Vₚ₁ represents the voltage across said piezoelectric assembly 12 connected to the primary winding 82 associated with the second input voltage V_{in 2}.

A person skilled in the art would then understand that in the example shown in FIG. 11, the control principle is the same as in the example shown in FIG. 12, except that instead of controlling the second output so as to provide a second output voltage V_{out_2}, the control is modified so that the current reverses and the second output becomes an input. Said input is controlled with respect to the first input. It is then as if the second input voltage V_{in_2} supplied power to the first input voltage V_{in_1} which as such supplied power to the output voltage Vₒᵤₜ. The above then makes possible, an independent control of the output voltage Vₒᵤₜ and of the current drawn from the second input voltage V_{in_2}.

In a variant of the example shown in FIG. 11, instead of connecting a piezoelectric assembly 12 to the secondary winding 84, a piezoelectric assembly 12 is connected to the primary winding 82 associated with the first input voltage V_{in_1}. According to such variant, the two input voltages V_{in_1}, V_{in_2} are then controlled with respect to the output voltage Vₒᵤₜ.

A person skilled in the art would understand that, in practice, on a winding 82, 84 where there is no piezoelectric assembly 12 connected, no control can be achieved for differentiating a current that would go rather to one output than to another. The exchanged current can hence be controlled on the windings 82, 84 to which a respective piezoelectric assembly 12 is connected; and the or each winding 82, 84 without piezoelectric assembly 12 undergoes the control, and compensates the total balance of the powers exchanged, the sum of the output powers being equal to the sum of the input powers excluding the losses.

Furthermore, in the present description and as shown in FIGS. 1 to 9, 13 and 15, the voltage between the first midpoints 38 is denoted by Vₚₐ and is equal to the potential difference (Vₚₐ₁−Vₚₐ₂), where Vₚₐ₁ is the potential of one of the first two midpoints 38, and Vₚₐ₂ is the potential of the other first midpoint 38. By convention, when the first switching assembly 30 includes only one first switching branch 32, the potential among Vₚₐ₁, Vₚₐ₂ which is not associated with the first midpoint 38 of the first switching branch 32 then corresponds to the potential Vᵢₙₙ, Vᵢₙₚ of one of the two input voltage application terminals 34 or to the potential of a respective end 88 of the primary winding 82. In the examples shown in FIGS. 4 to 10, the potential Vₚₐ₂ is equal to the lower potential Vᵢₙₙ of the input voltage.

When the electric power converter 10 is configured for receiving a plurality of distinct input voltages V_{in_k}, as in the example shown in FIG. 11, the voltage between the first midpoints 38 is denoted by V_{pa_k} for each first switching assembly 30 associated with the respective input voltage V_{in_k} and is equal to the difference of potential (V_{pa1,k}−V_{pa2,k}), where V_{pa1,k} is the potential of one of the first two midpoints 38, and V_{pa2,k} is the potential of the other first midpoint 38 of said first switching assembly 30, with aforementioned convention remaining applicable.

The voltage between the second midpoints 48 is denoted by V_{pb} and is equal to the potential difference (V_{pb2}−V_{pb1}), where V_{pb1} is the potential of one of the two second midpoints 48, and V_{pb2} is the potential of the other second midpoint 48. Also by convention, when the second switching assembly 40 includes only one second switching branch 42, the potential among V_{pb1}, V_{pb2} which is not associated with the second midpoint 48 of the second switching branch 42 then corresponds to the potential Vₒᵤₜₙ, Vₒᵤₜₚ of one of the two output voltage supply terminals 44 or that of a respective end 88 of the secondary winding 84. In the example shown in FIG. 7, the potential V_{pb1} is equal to the lower potential Vₒᵤₜₙ of the output voltage; and in the example shown in FIG. 8, the potential V_{pb2} is equal to said lower potential Vₒᵤₜₙ of the output voltage. In the example shown in FIG. 9, each potential V_{pb1}, V_{pb2} is equal to the potential of a respective end 88 of the secondary winding 84.

When the electrical energy converter 10 is configured for delivering a plurality of distinct output voltages V_{out_j}, as in the examples shown in FIGS. 10 and 12, the voltage between the second midpoints 48 is denoted by V_{pb_j} for each second switching assembly 40 associated with the respective output voltage V_{out_j}, and is equal to the difference of potential (V_{pb2,j}−V_{pb1,j}), where V_{pb1,j} is the potential of one of the two second midpoints 48, and V_{pb2,j} is the potential of the other second midpoint 48 of said second switching assembly 40, with the aforementioned convention remaining applicable.

The resonant frequency is the frequency at which the piezoelectric element 15 oscillates and consequently the current I_{L} thereof, shown in FIG. 1, oscillates. The conversion cycle is synchronized to a mechanical movement of the piezoelectric element 15, and the frequency of the control is then adjusted according to the mechanical oscillation frequency. In practice, the oscillation frequency depends on the operating point of the converter 10: values of the three voltage steps and of the output current. Depending on the operating point, the oscillation frequency typically varies between the so-called series resonance frequency of the piezoelectric element 15 (ωₛ=1√(Lᵣ·Cᵣ) where Lᵣ and Cᵣ correspond to the inductance and the capacitance of the resonant branch 54) and the so-called parallel resonance frequency of the piezoelectric element 15 (ωₚ=1√(Lᵣ·Cᵣ·C₀/(Cᵣ+C₀))), also called resonance frequency and antiresonance frequency of the piezoelectric element 15, respectively. The operating frequency of the converter 10 is then comprised between said two resonant and antiresonant frequencies of the piezoelectric element 15. The operating point varies slowly with respect to the oscillation frequency of the piezoelectric element 15. The operating point typically evolves at less than 10 kHz, whereas the oscillation frequency of the piezoelectric element 15 is typically greater than or equal to 100 kHz. As a result, the operating frequency of the converter 10 varies little from one period to the next.

As an optional addition, when the converter 10 comprises a plurality of piezoelectric assemblies 12 connected to the primary winding 82, said piezoelectric assemblies 12 at the primary, and the piezoelectric elements 15 forming same, are preferentially substantially identical to each other.

As an optional addition and in a similar manner, when the converter 10 comprises a plurality of piezoelectric assemblies 12 connected to the secondary winding 84, said piezoelectric assemblies 12 at the secondary winding, and the piezoelectric elements 15 forming same, are preferentially substantially identical to each other.

Piezoelectric assemblies 12 which are substantially identical to each other means that same have the same reference capacitance C₀ to within plus or minus 10% and the same resonance frequency to within plus or minus 10%.

As an optional addition, the piezoelectric assembly or assemblies 12 connected to the secondary winding 84 have a reference capacitance C₀ substantially equal to m times the reference capacitance C₀ of the piezoelectric assembly or assemblies 12 connected to the primary winding 82, to within plus or minus 50%.

In general, for the electrical energy converter 10 with the piezoelectric assemblies 12 and controlled by the electronic control device 20, the number of phases at substantially constant voltage is typically at least 2, preferentially equal to 3, while same can be greater than or equal to 4 along with the implementation of the control described in the application FIR 21 07345 filed on Jul. 7, 2021.

Each phase with a substantially constant voltage can be obtained from a combination of the input and output voltages, with an either positive or negative value, while taking into account the transformation ratio m of the electrical transformer 80, as explained thereafter, in particular with reference to Table 1. The energy converter 10 then makes it possible to exchange energy during the phases with a substantially constant voltage, and consequently with the combinations of voltages used, to obtain said phases with a substantially constant voltage. In particular, it is possible to transfer energy from a substantially constant voltage phase of low voltage to a substantially constant voltage phase of higher voltage, and by the combination of the above-mentioned combinations, to finally obtain a step-down converter, which may seem counterintuitive. Conversely, it is also possible to transfer energy from a phase with a substantially constant voltage of high voltage to a phase with a substantially constant voltage of lower voltage, and by the combination of the above-mentioned combinations, to finally obtain a voltage step-up converter. A person skilled in the art would then understand that it is possible to have a step-up cycle seen by the piezoelectric assemblies 12 while the electrical energy converter 10 is a step-down converter, and conversely to have a step-down cycle seen by the piezoelectric assemblies 12, while the electrical energy converter 10 is a step-up converter.

By convention, if a current is supplied to the piezoelectric assemblies 12 during the phase with substantially constant voltage corresponding to the highest voltage during a resonance cycle, then the cycle is considered as a step-down cycle for the piezoelectric assemblies 12. Conversely, if a current is delivered, or drawn, from the piezoelectric assemblies 12 during said phase with a substantially constant voltage for which the voltage is highest during the resonance cycle, then the cycle is considered to be a step-up cycle for the piezoelectric assemblies 12. As indicated above, the conversion cycle seen by the piezoelectric assemblies 12 is likely to be a step-up cycle while the electrical energy converter 10 works as a step-down converter, and conversely, the conversion cycle seen by the piezoelectric assemblies 12 is likely to be a step-down cycle while the electrical energy converter 10 works as a step-up converter.

The electronic control device 20 is configured for controlling the electrical energy converter 10, in particular for controlling the switches 36, 46 of the converter so as to alternate, during a respective resonance cycle of the piezoelectric assemblies 12, phases with a substantially constant voltage across the piezoelectric assemblies 12 and phases with a substantially constant load, i.e. in a substantially open circuit, across said piezoelectric assemblies 12.

The electronic control device 20 is e.g. produced in the form of an electronic circuit including one or a plurality of electronic components.

In a variant, the electronic control device 20 is produced in the form of a programmable logic component, such as an FPGA (Field Programmable Gate Array), or in the form of an integrated circuit, such as an ASIC (Application Specific Integrated Circuit) or in the form of a computer, such as a microcontroller, a processor.

As an optional addition, when the converter 10 comprises a plurality of piezoelectric assemblies 12, the electronic control device 20 is further configured for controlling the switches 36, 46 of the converter in order to make all the piezoelectric assemblies 12 operate at substantially the same resonant frequency, such as to the same resonant frequency within plus or minus 10%.

Each of the first 36 and second 46 switches is preferentially a switch which is unidirectional with regard to current and unidirectional with regard to voltage. The switch 36, 46 comprises e.g. a transistor, or a diode, or further a transistor and a diode in antiparallel (not shown). The switch 36, 46 is preferentially formed by the transistor, or by the diode, or else by the transistor and the diode in antiparallel. In a variant, the switch 36, 46 comprises an association of a plurality of transistors, and preferentially consists of such an association of a plurality of transistors. As a further variant, the switch 36, 46 comprises a mechanical switch, such as a micro-switch MEMS (Micro-Electro-Mechanical System).

The transistor is e.g. an insulated gate field effect transistor, also called MOSFET (Metal Oxide Semiconductor Field Effect Transistor). In a variant, the transistor is a bipolar transistor; an insulated gate bipolar transistor, also called IGBT (Insulated Gate Bipolar Transistor); a silicon (Si) transistor, a GaN (Gallium Nitride) transistor; a silicon carbide (SiC) transistor, a diamond transistor, or a thyristor.

As an optional addition, a winding 82, 84 includes between the ends 88 thereof, at least one intermediate point 90 connected to a respective switching assembly 30, 40 or to a respective terminal for applying an input voltage 34 or for supplying an output voltage 44.

According to such optional addition, in the example shown in FIG. 9, the secondary winding 84 includes between the ends 88 thereof, an intermediate point 90 connected to a respective output voltage supply terminal 44, namely the terminal having the higher output voltage potential Vₒᵤₜₚ. In the example shown in FIG. 10, the secondary winding 84 includes between the ends 88 thereof, a plurality of intermediate points 90. Certain intermediate points 90 are connected to a respective second switching assembly 40, namely the assembly associated with the output voltage V_{out_2}. Another intermediate point 90 is connected to a plurality of respective output voltage supply terminals 44, namely the terminals of higher output voltage potentials Vₒᵤₜₚ₁, Vₒᵤₜₚ₂.

According to such optional addition, in a variant not shown, the primary winding 82 includes between the ends 88 thereof, an intermediate point 90 connected to a respective first switching assembly 30, or to a respective input voltage application terminal 34.

A person skilled in the art would observe that, with the converter 10 according to the invention and due to the presence of at least one piezoelectric assembly 12 connected to the primary winding 82 or to the secondary winding 84, respectively, the or each piezoelectric assembly 12 further makes it possible to reduce, or even eliminate, a DC component via the capacitive behavior thereof at low frequency, i.e. for a frequency less than one-tenth of the frequency of a first resonance mode. Thus, if the voltage Vₚₐ and/or the voltage V_{pb} have a DC component, same would be reduced, or even eliminated, by the piezoelectric assembly 12 connected to the primary winding 82 or to the secondary winding 84, respectively. The voltages at the primary V1 and at the secondary V2 then have a substantially zero DC component, which leads to a better operation of the electrical transformer 80 without any risk of current drift.

Furthermore, even if the electrical transformer 80 provides a first level of isolation, the piezoelectric assembly or assemblies 12 add a supplementary level of isolation, e.g. for reaching a reinforced level of isolation which provides isolation e.g. even in the event of the occurrence of a first fault.

The operation of the converter 10 according to the invention is then similar to the operation of each of the electrical energy converters described in the applications FR 21 12925, FR 21 12926 and FR 21 12933 filed on Dec. 3, 2021, unlike the voltage values during the phases at substantially constant voltage across the piezoelectric assemblies 12, also called voltage step values, said voltage step values being, due to the transformation ratio m of the electrical transformer 80, likely to differ from the step values described in the aforementioned applications.

In the example shown in FIGS. 1 to 9, 13 and 15, excluding the DC component and due to the topology of the converter 10, the electronic control device 20 is then configured for controlling, during phases at substantially constant voltage across the piezoelectric assemblies 12, the switches 36, 46 of the converter 10, so as to have the value of the voltage of each of the phases at substantially constant voltage, chosen from the group of values defined in table 1 hereinafter for each of the figures:

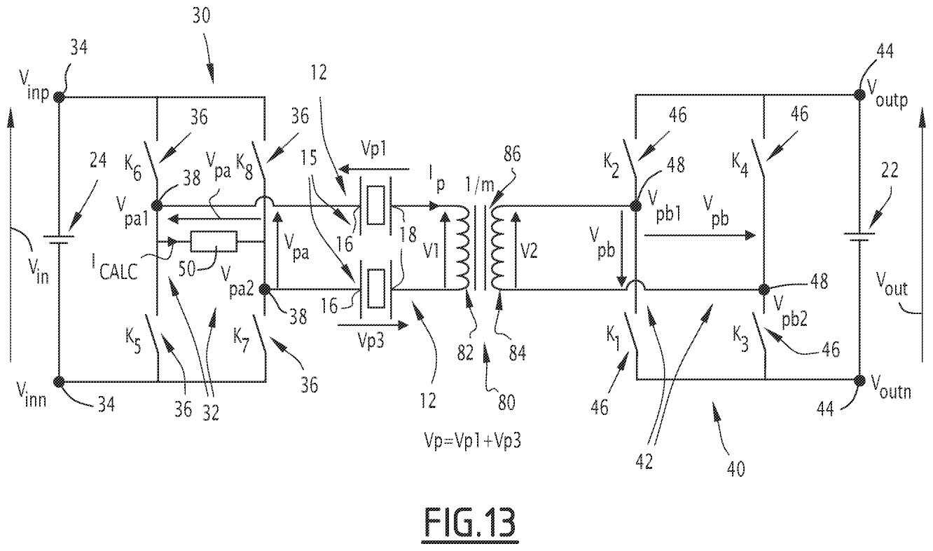

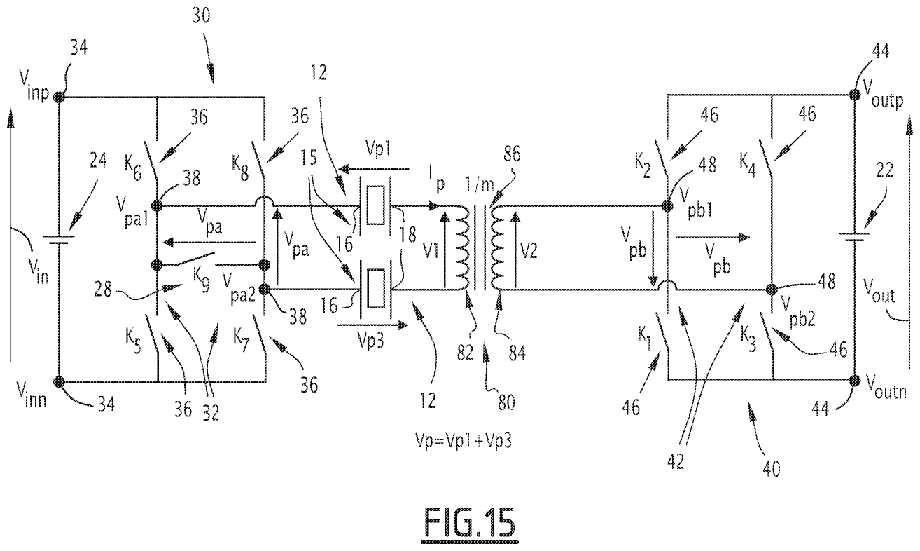

TABLE 1

| | Possible values for each voltage step, |
|---|---|
| Figure | with the converter of the respective figure |
| FIG. 1 | 0; −Vᵢₙ; +Vᵢₙ; −mVₒᵤₜ; +mVₒᵤₜ; −Vᵢₙ − mVₒᵤₜ; −Vᵢₙ + |
| | mVₒᵤₜ; Vᵢₙ − mVₒᵤₜ; Vᵢₙ + mVₒᵤₜ |
| FIG. 2 | 0, −Vᵢₙ; +Vᵢₙ; −mVₒᵤₜ; +mVₒᵤₜ; −Vᵢₙ − mVₒᵤₜ; −Vᵢₙ + |
| | mVₒᵤₜ; Vᵢₙ − mVₒᵤₜ; Vᵢₙ + mVₒᵤₜ |
| FIG. 3 | 0; −Vᵢₙ; +Vᵢₙ; −mVₒᵤₜ; + mVₒᵤₜ; −Vᵢₙ − mVₒᵤₜ; Vᵢₙ + |
| | mVₒᵤₜ; Vᵢₙ − mVₒᵤₜ; Vᵢₙ + mVₒᵤₜ |
| FIG. 4 | 0; +Vᵢₙ; −mVₒᵤₜ; +mVₒᵤₜ; Vᵢₙ − mVₒᵤₜ; Vᵢₙ + mVₒᵤₜ |
| FIG. 5 | 0; +Vᵢₙ; −mVₒᵤₜ; +mVₒᵤₜ; Vᵢₙ − mVₒᵤₜ; Vᵢₙ + mVₒᵤₜ |
| FIG. 6 | 0; +Vᵢₙ; −mVₒᵤₜ; +mVₒᵤₜ; Vᵢₙ − mVₒᵤₜ; Vᵢₙ + mVₒᵤₜ |
| FIG. 7 | 0; +Vᵢₙ; +mVₒᵤₜ; Vᵢₙ + mVₒᵤₜ |
| FIG. 8 | 0; +Vᵢₙ; −mVₒᵤₜ; Vᵢₙ − mVₒᵤₜ |
| FIG. 9 | 0; +Vᵢₙ; −mVₒᵤₜ; +mVₒᵤₜ; Vᵢₙ − mVₒᵤₜ; Vᵢₙ + mVₒᵤₜ |
| FIG. 13 | 0; −Vᵢₙ; +Vᵢₙ; −mVₒᵤₜ; +mVₒᵤₜ; −Vᵢₙ − mVₒᵤₜ; −Vᵢₙ + |
| | mVₒᵤₜ; Vᵢₙ − mVₒᵤₜ; Vᵢₙ + mVₒᵤₜ |
| FIG. 15 | 0; −Vᵢₙ; +Vᵢₙ; −mVₒᵤₜ; +mVₒᵤₜ; −Vᵢₙ − mVₒᵤₜ; −Vᵢₙ + |
| | mVₒᵤₜ; Vᵢₙ − mVₒᵤₜ; Vᵢₙ + mVₒᵤₜ |

where Vᵢₙ represents the input voltage, Vₒᵤₜ represents the output voltage and m represents the transformation ratio of the electrical transformer 80 and taking into account the preceding equations (2) to (4).

In the examples shown in FIGS. 7 and 8, a person skilled in the art would observe that, due to the topology of the converter 10, the voltage Vₚₐ cannot be negative and then necessarily includes a DC component, and the same is true for the voltage V_{pb}. Since the voltages at the primary V1 and at the secondary V2 do not in principle have a DC component, the DC component of the voltage Vₚₐ is then eliminated by the piezoelectric assembly 12 arranged between the voltage Vₚₐ and the primary winding 82, in order to form the voltage at the primary V1. A DC component is then reintroduced into the voltage V_{pb} with respect to the voltage at the secondary V2, via the piezoelectric assembly 12 arranged between the primary winding 84 and the voltage V_{pb}. Compared with a cycle of a converter of the prior art without an electrical transformer, it is then possible to have a modification of the DC component of the total piezoelectric voltage Vₚ. However, in a steady state, there is a balance of the loads exchanged on each of the piezoelectric assemblies 12 over a period of mechanical oscillation, and the possible presence of a DC voltage component on the piezoelectric assemblies 12 thus does not modify the balance of the energy exchanged over a period of mechanical oscillation (∫I_{L}·V_{pi_moy}dt=0). A person skilled in the art would then understand the precision “excluding the DC component” as indicated above, for the presentation of the possible values of the voltage steps. Indeed, it is possible for a DC component to be added during the phases at substantially constant voltage and on each of the piezoelectric assemblies 12, without in this way modifying the behavior of the converter 10 according to the invention, in terms of output power, of the amplitude of the current I_{L} flowing through the piezoelectric elements 15, or further of regulation.

In the example shown in FIG. 9, the switches K₇ and K₈ have been removed at the primary compared to a topology with two first switching branches 32, and a person skilled in the art would observe that, in a variant, the switches K₅ and K₆ could have been removed, by then connecting an intermediate point 90 of the primary winding 82 to the either the lower potential Vᵢₙₙ or to the higher potential Vᵢₙₚ of the input voltage.

Similarly, the switches K₂ and K₄ have been removed at the secondary compared to a topology with two second switching branches 42, while connecting the intermediate point 90 of the secondary winding 84 to the higher output voltage potential Vₒᵤₜₚ, and a person skilled in the art would observe that, in a variant, the switches K₁ and K₃ could have been removed, by then connecting the intermediate point 90 of the secondary winding 84 to the lower potential Vₒᵤₜₙ of the output voltage.

A person skilled in the art would note that in the example shown in FIG. 9, the piezoelectric assembly 12 cannot be placed on the side of the winding 82, 84 with the intermediate point 90, because if same is in series with a switch, same would be disconnected over at least half a period and it will then not be possible to apply any voltage step over said half period. And if the piezoelectric assembly 12 is connected in series with the intermediate point 90, as the latter has to exchange a substantially zero average quantity of loads over a period (load balance), then there can be no power exchanged with the substantially constant output voltage over a resonance period. On the other hand, it is possible to completely reverse the input and the output in order to find an intermediate point 90 at the primary and the piezoelectric assembly or assemblies 12 at the secondary.

In the example shown in FIG. 10, the voltages at the secondary V2,1, V2,2 and V2,3 are proportional to each other according to the ratios m1′=V1/V2,1; m2″=V1/V2,2 and m3″=V1/V2,3 relating to each of the outputs of the electrical transformer 80.

In the example shown in FIG. 10, the electrical transformer 80 was represented with only one secondary winding 84 and outputs which use, to a greater or lesser extent, turns of the same secondary winding 84.

In a variant, the electrical transformer 80 includes a plurality of secondary windings 84 completely independent of one another, e.g. so as to obtain secondary voltages V2, V2 isolated from one another, as in the example shown in FIG. 12.

A person skilled in the art would further observe that it is possible to regulate separately each of the outputs by successively connecting each of the outputs, in the manner shown in FIGS. 17 and 18 of the patent FR 3 086 472. Typically, by cutting the voltage steps wherein the output voltage appears, into voltage sub-steps with the different output voltages. In such case, certain switches K_{1,1}, K_{2,1}, K_{3,1}, K_{4,1}, K_{1,2}, K_{2,2}, K_{3,2}, K_{4,2} of the converter 10 shown in FIG. 10 have to be bidirectional with regard to voltage, so as to be able to isolate an output while a current is supplied to another output requiring a higher voltage at the primary V1.

In the example shown in FIG. 10, the piezoelectric assembly 12 is arranged at the primary, and same is shared for the operation of all the outputs, and the current of the piezoelectric assembly 12 is then divided into a plurality of output currents.

In a variant, it is possible to connect a piezoelectric assembly 12 to each of the outputs, as in the example shown in FIG. 12. In such case, for controlling each output individually, it is not essential to use bidirectional transistors with regard to voltage. In fact, for having in common, the same evolution of the voltage Vₚₐ, starting from the moment when the cycles for the output voltages V_{out_1} and V_{out_2} are compatible, each of the output voltages can be controlled independently without passing through sub-steps. By a differentiated control of the voltages V_{pb_1} and V_{pb_2}, it is possible to obtain differentiated cycles for the first and second piezoelectric voltages V_{p_out1} and V_{p_out2}, and thus to control the output voltages V_{out_1} and V_{out_2} in a differentiated manner.

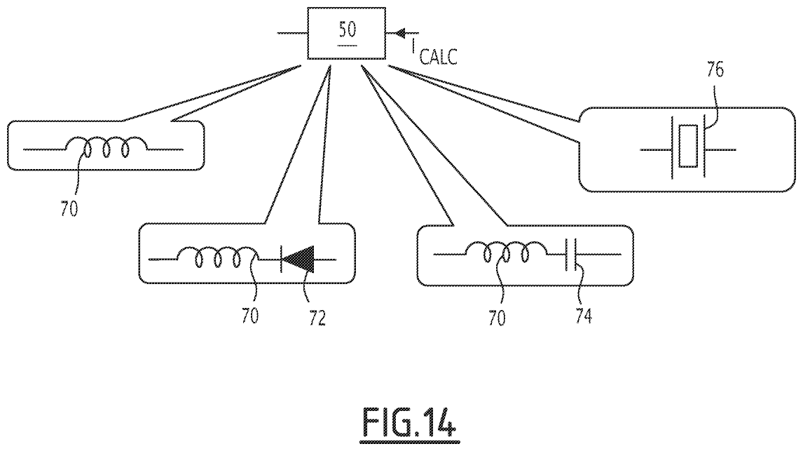

In FIGS. 13 and 14, according to a supplementary aspect of the invention and when the converter 10 comprises at least one pair of piezoelectric assemblies 12 connected to the same respective winding 82, 84, the converter 10 further comprises at least one switching-aid circuit 50, each switching-aid circuit 50 being connected between the first ends 16 of a respective pair of piezoelectric assemblies 12, corresponding to the first midpoints 38 of the first switching assembly 30 when said pair of piezoelectric assemblies 12 is connected to the first switching assembly 30, and corresponding to the second midpoints 48, respectively, of the second switching assembly 40 when said pair of piezoelectric assemblies 12 is connected to the second switching assembly 40. Each switching-aid circuit 50 being configured for discharging, via the circulation of a previously received current, a parasitic capacitance of at least one switch 36, 46 of the respective switching assembly 30, 40 to which same is connected, and charging, respectively, at least one parasitic capacitance of another switch 36, 46 of said switching assembly 30, 40.

In the example shown in FIG. 13, the converter 10 comprises a single switching-aid circuit 50 connected to the first switching assembly 30.

In a variant, not shown, the converter 10 comprises a single switching-aid circuit 50 connected to the second switching assembly 40.

In a variant, not shown, the converter 10 comprises two switching-aid circuits 50, a first switching-aid circuit being connected to the first switching assembly 30 and a second switching-aid circuit being connected to the second switching assembly 40.

Each switching-aid circuit 50 is configured, via the circulation of a previously received current I_{CALC}, for discharging at least one parasitic capacitance of a switch 36, 46, preferentially a switch to be closed, from the respective switching assembly 30, 40 to which same is connected; for charging, respectively, at least one parasitic capacitance of another switch 36, 46, preferentially a switch to be opened or to be kept open, of said switching assembly 30, 40.

Each of the switches of said switching assembly 30 is open when the previously received current flows through the switching-aid circuit 50.

Following said current flow, the switch(es) 36, 46, the parasitic capacitance of which has been discharged by the switching-aid circuit 50 is/are closed. The other switch(es) 36, 46 of which parasitic capacitance was charged by the switching-aid circuit 50 remains/remain open. A residual current from the switching-aid circuit 50 can continue to flow.

Each switching-aid circuit 50 includes e.g. an inductor 70; or a first assembly formed by the inductor 70 and a diode 72 connected in series; or a second assembly formed by the inductor 70 and a capacitor 74 connected in series; or an additional piezoelectric element 76, as shown in FIG. 14.

Each switching-aid circuit 50 is e.g. an inductor 70, the inductor 70 preferentially consisting of a coil and of a magnetic circuit. In a variant, each switching-aid circuit 50 is in the form of the first assembly of the inductor 70 and of the diode 72 connected in series, and preferentially consisting of said first assembly of the inductor 70 and of the diode 72. As a further variant, each switching-aid circuit 50 is in the form of the second assembly of the inductor 70 and of the capacitor 74 connected in series, and preferentially consisting of said second assembly of the inductor 70 and of the capacitor 74. As a further variant, each switching aid circuit 50 is in the form of the additional piezoelectric element 76, and preferentially consists of the additional piezoelectric element 76.

As a further variant, the electrical transformer 80 is dimensioned so as to have an inductive behavior in the form of an equivalent parasitic inductor placed between the terminals of the primary winding 82 and/or between the terminals of the secondary winding 84 of the transformer. This parasitic inductor, generally called a magnetizing inductor, then makes it possible to provide the function of switching-aid circuit 50. Such a magnetizing inductor is illustrated in plate 15 in the presentation of Feb. 19, 2019 by Abdallah Darkawi, entitled “Single-Phase Transformer”.

In the example of embodiment where the switching-aid circuit 50 is in the form of the inductor 70 alone, the inductor 70 has the current thereof increased over half a period, i.e. when the voltage at the terminals thereof is positive; then the current decreases over the other half-period, i.e. when the voltage at the terminals thereof is negative. Such example of embodiment of the switching-aid circuit 50 preferentially requires that the voltage at the terminals the inductor 70 has a substantially zero mean, at the risk otherwise of having a current drift. If the switching-aid circuit 50 is connected to the second assembly 40, in particular between the second midpoints 48, the voltage at the terminals of the inductor 70 is the voltage V_{pb}. Consequently, if the switching-aid circuit 50 is connected to the first assembly 30, in particular between the first midpoints 38, the voltage at the terminals of the inductor 70 is the voltage Vₚₐ.

The variant wherein the switching-aid circuit 50 is in the form of the inductor 70 and of the diode 72 connected in series, makes it possible to charge the inductor 70 only over half a period with the correct polarity, in particular for cycles where the current I_{CALC} is received during a period of time with only one polarity. In particular, the diode 72 then makes it possible to prevent charging the inductor 70 with an inverse current. Such unidirectional current operation further makes it possible to reduce the effective current seen by the inductor 70 and hence to reduce the losses. Moreover, the switching-aid circuit 50 according to such variant is not sensitive to the presence of a DC component from the moment when the DC component is along the direction of blocking of the diode 72.

The variant wherein the switching-aid circuit 50 is in the form of the inductor 70 and of the capacitor 74 connected in series makes it possible—compared with the example of the inductor 70 alone—to reduce or even eliminate a possible DC component. Nevertheless, the capacitor 74 can be quite bulky. Indeed, the voltage at the terminals of the capacitor 74 has to change little, i.e. in a small proportion, with respect to the input voltage Vᵢₙ or to the output voltage Vₒᵤₜ, e.g. to have an amplitude less than 50% of the input voltage Vᵢₙ or output voltage Vₒᵤₜ.

According to the variant wherein the switching-aid circuit 50 is in the form of the additional piezoelectric element 76, from the moment the converter 10 is controlled between the resonance and antiresonance frequency of the additional piezoelectric element 76, the latter starts to oscillate and to produce a current I_{CALC} substantially in quadrature with the voltage at the terminals thereof, such as the voltage V_{pb} if the additional piezoelectric element 76 is connected to the second assembly 40 between the second midpoints 48, or further the voltage Vₚₐ if the additional piezoelectric element 76 is connected to the first assembly 30 between the first midpoints 38. The current I_{CALC} then passes through an extrema, which makes it possible to provide the inversion function of the voltage V_{pb}, or of the voltage Vₚₐ, respectively.

The additional piezoelectric element 76 is typically at least 3 times smaller than the piezoelectric element(s) 15 of the converter 10, the additional piezoelectric element 76 having only to charged/discharge the parasitic capacitances of the switches 36, 46. The parasitic capacitance of the switches 36, 46 is considered to be at least three times smaller than the reference capacitance C₀ of the piezoelectric element or elements 15 of the converter 10. Such variant wherein the switching-aid circuit 50 is in the form of the additional piezoelectric element 76, is insensitive to any DC component (whatever the polarity thereof), and the switching-aid circuit 50 is adapted for being connected to the first assembly 30 (voltage Vₚₐ) and to the second assembly 40 (voltage V_{pb}).

In other words, the reference capacitance of the additional piezoelectric element 76 is at least three times less than the reference capacitance C₀ of each piezoelectric assembly 12 connected between respective first 38 and second 48 midpoints.

In FIG. 15, according to another supplementary aspect of the invention and when the converter 10 comprises at least one pair of piezoelectric assemblies 12 connected to the same respective winding 82, 84, the converter 10 further comprises a supplementary switch 28 directly connected between the first ends 16 of said pair of piezoelectric assemblies 12, said first ends 16 directly connected to each other via the supplementary switch 28 being connected to the same respective switching assembly 30, 40.

In the example shown in FIG. 15, the converter 10 comprises only one supplementary switch 28 directly connected between the first ends 16 of the pair of piezoelectric assemblies 12 connected to the primary winding 82.

In a variant (not shown), the converter 10 comprises only one supplementary switch 28 directly connected between the first ends 16 of the pair of piezoelectric assemblies 12 connected to the secondary winding 84.

As a further variant (not shown), the converter 10 comprises two supplementary switches 28, namely a first supplementary switch 28 directly connected between the first ends 16 of the pair of piezoelectric assemblies 12 connected to the primary winding 82 and a second supplementary switch 28 directly connected between the first ends 16 of the pair of piezoelectric assemblies 12 connected to the secondary winding 84.

As a further variant (not shown), and when the converter 10 comprises a plurality of pairs of piezoelectric assemblies 12, each connected to a respective winding 82, 84, the converter 10 preferentially comprises a supplementary switch 28 for each pair of piezoelectric assemblies 12, each supplementary switch 28 then being connected between the first ends 16 of a respective pair.

In the example shown in FIG. 15, the supplementary switch 28 is also denoted by K₉.

Each supplementary switch 28 is preferentially a bidirectional switch with regard to voltage. Each supplementary switch 28 comprises e.g. two unidirectional, i.e. one-direction switches with regard to voltage, placed head-to-tail in series. Each unidirectional switch comprises e.g., a transistor, or a diode, or further a transistor and a diode in antiparallel (not shown). Each unidirectional switch preferentially consists of a transistor, or of a diode, or further by a transistor and a diode in antiparallel.

A person skilled in the art would observe that each supplementary switch 28 is, in a variant, a unidirectional switch with regard to voltage.

According to such supplementary aspect of the invention, the electronic control device 20 is further configured for controlling at least one respective supplementary switch 28 in the closed position during at least one phase with substantially constant voltage.

A person skilled in the art would then understand that when the converter 10 comprises a respective supplementary switch 28 directly connected between the first ends 16 of a respective pair of piezoelectric assemblies 12 connected to the primary winding 82, the control in the closed position of said supplementary switch 28 makes it possible to force to zero the voltage Vₚₐ between said first ends 16.

Similarly, when the converter 10 comprises a respective supplementary switch 28 directly connected between the first ends 16 of a respective pair of piezoelectric assemblies 12 connected to the secondary winding 84, then the control in the closed position of said supplementary switch 28 makes it possible to force to zero the voltage V_{pb} between the first ends 16.

Similarly, when the converter 10 comprises two supplementary switches 28 connected to the first ends 16 of two respective pairs of piezoelectric assemblies 12 connected to the primary winding 82 and to the secondary winding 84, i.e. both the first supplementary switch 28 directly connected between the first ends 16 of a respective pair of piezoelectric assemblies 12 connected to the primary winding 82 and a second supplementary switch 28 directly connected between the first ends 16 of the other pair of piezoelectric assemblies 12 connected to the secondary winding 84, then the control in the closed position of the first and second supplementary switches 28 makes it possible to force both the voltage Vₚₐ to the zero value and the voltage V_{pb} to the zero value, and therefore to force to zero, the total piezoelectric voltage Vₚ of the two pairs of piezoelectric assemblies 12.

1. An electronic electrical energy conversion system adapted for converting one or a plurality of input voltages into one or a plurality of output voltages, the conversion system comprising:
an electrical energy converter configured for delivering N separate output voltage(s) from E distinct input voltage(s), where E and N are each an integer greater than or equal to 1, the converter comprising:
E first switching assembly or assemblies, each associated with a respective input voltage and including at least two first switches, each first switch being connected to an application terminal of the respective input voltage;
N second switching assembly or assemblies, each associated with a respective output voltage and including at least two second switches, each second switch being connected to a terminal for supplying the respective output voltage;
at least one piezoelectric assembly, each being connected to one of the first and second switches, and including at least one piezoelectric element;
an electronic control device for the electrical energy converter, the electronic control device being configured for controlling, during a respective resonance cycle of the piezoelectric assembly or assemblies, a switching of each of the first and second switches so as to alternate phases of substantially constant voltage across the one or a plurality of piezoelectric assemblies and phases of substantially constant load across the one or a plurality of piezoelectric assemblies,
characterized in that the converter further comprises an electrical transformer including at least one primary winding and at least one secondary winding, each primary winding being connected to a first switching assembly, each secondary winding being connected to a second switching assembly, and each piezoelectric assembly being connected between a respective switch and a respective winding.

2. The system according to claim 1, wherein each piezoelectric assembly is connected between a first switch and a primary winding or between a second switch and a secondary winding.

3. The system according to claim 1, wherein each winding is connected to at least one piezoelectric assembly or has between the ends thereof, a voltage of substantially zero mean value over a respective resonance cycle, the control device then being configured for controlling the switches of the switching assembly connected to said winding so as to obtain said voltage of substantially zero mean.

4. The system according to claim 1, wherein the converter comprises a plurality of piezoelectric assemblies, and each winding is connected to at least one piezoelectric assembly.

5. The system according to claim 1, wherein the converter comprises only one piezoelectric assembly connected to a respective winding, and the or each other winding has between the ends thereof, a substantially zero average voltage over a respective resonance cycle.

6. The system according to claim 1, wherein least one first switching assembly is in the form of a first switching bridge including at least one first switching branch, each first switching branch being connected between two terminals for applying a respective input voltage and including at least two first switches connected in series and connected to each other at a first mid-point.

7. The system according to claim 6, wherein each first switching assembly is in the form of a respective first switching bridge.

8. The system according to claim 6, wherein at least one first switching assembly includes two first switching branches.

9. The system according to claim 8, wherein each first switching assembly includes two first switching branches.

10. The system according to claim 6, wherein a piezoelectric assembly is connected between a first midpoint and a respective primary winding.

11. The system according to claim 1, wherein at least one second switching assembly is in the form of a second switching bridge including at least one second switching branch, each second switching branch being connected between two terminals for supplying a respective output voltage and including at least two second switches connected in series and connected together at a second midpoint.

12. The system according to claim 11, wherein each second switching assembly is in the form of a respective second switching bridge.

13. The system according to claim 11, wherein at least one second switching assembly includes two second switching branches.

14. The system according to claim 13, wherein each second switching assembly includes two second switching branches.

15. The system according to claim 11, wherein a piezoelectric assembly is connected between a second midpoint and a respective secondary winding.

16. The system according to claim 1, wherein a winding has, between the ends thereof, at least one intermediate point connected to a respective switching assembly or to a respective terminal for applying an input voltage or supplying an output.

17. The system according to claim 1, wherein the converter comprises a pair of piezoelectric assemblies connected to the same respective winding, and in addition a supplementary switch directly connected between ends of said pair of piezoelectric assemblies, said ends directly connected to each other via the supplementary switch, being connected to the same respective switching assembly.

18. The system according to claim 1, wherein the converter comprises a pair of piezoelectric assemblies connected to the same respective winding, and in addition a switching-aid circuit connected between ends of said pair of piezoelectric assemblies, said ends connected to each other via the switching-aid circuit, being connected to the same respective switching assembly, the switching-aid circuit being configured, via the flow of a previously received current, for discharging a parasitic capacitance of at least one switch of the respective switching assembly to which same is connected, and respectively charge at least one parasitic capacitance of another switch of said switching assembly;

19. The system of claim 18, wherein the switching-aid circuit includes an element selected from the group consisting of: an inductor; a first assembly consisting of an inductor and a diode connected in series; a second assembly consisting of an inductor and a capacitor connected in series; and an additional piezoelectric element.

20. The system according to claim 19, wherein the switching-aid circuit consists of one element chosen from said group consisting of: an inductor; a first assembly consisting of an inductor and a diode connected in series; a second assembly consisting of an inductor and a capacitor connected in series; and an additional piezoelectric element.

21. The system according to claim 19, wherein the inductor is in the form of a parasitic inductor of the respective winding to which the pair of piezoelectric assemblies is connected.

22. The system according to claim 1, wherein the electrical transformer is an air transformer or a magnetic transformer, the magnetic transformer further including a magnetic core, each winding then being arranged around the core.

23. The system according to claim 22, wherein the electrical transformer is an autotransformer.
